(19) United States
(12) Patent Application Publication
(10) Pub. No.: US 2025/0038473 A1
(43) Pub. Date: Jan. 30, 2025

(54) LIGHT EMITTING DEVICE AND DISTANCE MEASURING DEVICE

(71) Applicant: SONY SEMICONDUCTOR SOLUTIONS CORPORATION, KANAGAWA (JP)

(72) Inventor: SHOGO ONO, KANAGAWA (JP)

(21) Appl. No.: 18/710,788

(22) PCT Filed: Oct. 25, 2022
(86) PCT No.: PCT/JP2022/039754

§ 371 Date: May 16, 2024

(30) Foreign Application Priority Data
Nov. 24, 2021 (JP) 2021-190354

(51) Int. Cl. H01S 5/026; G01S 7/481; H01S 5/00; H01S 5/02253; H01S 5/42

(52) U.S. Cl. CPC H01S 5/0267; G01S 7/4815; H01S 5/0064; H01S 5/02253; H01S 5/0261; H01S 5/423

(57) ABSTRACT

Provided are a light emitting device and a distance measuring device capable of providing a light emitting element on a substrate in a suitable state.

A light emitting device of the present disclosure includes: a first substrate; a light emitting element provided on a lower surface of the first substrate; a lens provided on an upper surface of the first substrate and having a convex shape or a concave shape; a structure body that is provided on the upper surface of the first substrate, has a protruding shape or a recessed shape, and is different from the lens; and a film provided on the upper surface of the first substrate, the film including a first portion disposed on the lens or forming the lens, and a second portion disposed on the structure body or forming the structure body, in which, in a case where the lens has a convex shape, the structure body has a protruding shape, and a height of an uppermost portion of the first portion is higher than a height of an uppermost portion of the second portion, or the structure body has a recessed shape, and in a case where the lens has a concave shape, the structure body has a recessed shape.

### TECHNICAL FIELD

Embodiments of the present disclosure relate to a light emitting device and a distance measuring device.

### BACKGROUND ART

As a type of semiconductor laser, a surface-emitting laser such as a vertical cavity surface emitting laser (VCSEL) is known. In general, in a light emitting device utilizing a surface emitting laser, multiple light emitting elements are provided in a two-dimensional array on a front surface or a back surface of a substrate.

### CITATION LIST

### Patent Document

### Patent Document 1: Japanese Unexamined Patent Application Publication No. 2004-526194

### SUMMARY OF THE INVENTION

### Problems to be Solved by the Invention

When dicing (individualizing) a substrate including a light emitting element, for example, a dicing tape is bonded to the substrate, the substrate is irradiated with a laser, and the dicing tape is extended. As a result, the substrate is divided into multiple chips.

However, when the dicing tape is extended, an adhesive material of the dicing tape may be extended, and an edge portion of the chip may be peeled off from the dicing tape. In this case, there is a possibility that the adhesive material of the dicing tape is torn off near the edge portion of the chip, and the adhesive material of the dicing tape adheres to the chip. As a result, there is a possibility that the chip to which the adhesive material adheres becomes a defective product. In this way, when the substrate including the light emitting element is processed, a state of the substrate may be deteriorated.

Therefore, the present disclosure provides a light emitting device and a distance measuring device capable of providing a light emitting element on a substrate in a suitable state.

### Solutions to Problems

A light emitting device according to a first aspect of the present disclosure includes: a first substrate; a light emitting element provided on a lower surface of the first substrate; a lens provided on an upper surface of the first substrate and having a convex shape or a concave shape; a structure body that is provided on the upper surface of the first substrate, has a protruding shape or a recessed shape, and is different from the lens; and a film provided on the upper surface of the first substrate, the film including a first portion disposed on the lens or forming the lens, and a second portion disposed on the structure body or forming the structure body, in which, in a case where the lens has a convex shape, the structure body has a protruding shape, and a height of an uppermost portion of the first portion is higher than a height of an uppermost portion of the second portion, or the structure body has a recessed shape, and in a case where the lens has a concave shape, the structure body has a recessed shape. As a result, it is possible to provide the light emitting element on the first substrate in a suitable state. For example, by stopping progress of peeling of the dicing tape by using this structure body, it is possible to suppress adhesion of the adhesive material of the dicing tape to the first substrate, whereby a state of the first substrate can be favorably maintained.

Furthermore, in this first aspect, the lens may be a convex lens, a concave lens, a Fresnel lens, or a binary lens. As a result, for example, a shape of the lens can be made a convex shape or a concave shape.

Furthermore, in the first aspect, one or more of the light emitting elements may be provided on the lower surface of the first substrate, one or more of the lenses may be provided on the upper surface of the first substrate, and the light emitting element and the lens may correspond to each other at 1:1, N:1, or 1:N (N is an integer of 2 or more). As a result, for example, a size of the lens can be set to various sizes.

Furthermore, in the first aspect, the structure body may have a shape annularly surrounding the lens. As a result, for example, this structure body can be disposed in a wide range around the lens, and progress of peeling of the dicing tape can be stopped in a wide range.

Furthermore, in the first aspect, the structure body may have a shape in which a corner on an inner peripheral side or an outer peripheral side is rounded. As a result, for example, progress of peeling of the dicing tape can be suitably stopped by using this structure body.

Furthermore, the light emitting device of the first aspect may include, as the structure body, multiple structure bodies provided at multiple corners or edges of the upper surface of the first substrate. As a result, for example, these structure bodies can be disposed only in the vicinity of the corners or the vicinity of the edges of the upper surface of the first substrate.

Furthermore, in the first aspect, the multiple structure bodies may be arranged in an annular shape so as to annularly surround the lens. As a result, for example, these structure bodies can be disposed in a wide range around the lens, and progress of peeling of the dicing tape can be stopped in a wide range.

Furthermore, in the first aspect, a shape of a longitudinal cross section of the structure body may be a quadrangular shape, a triangular shape, a convex lens shape, or a concave lens shape. As a result, for example, the shape of the structure body can be made a protruding shape or a recessed shape.

Furthermore, in this first aspect, a distance between a side surface of the first substrate and the structure body may be 10 to 100 μm. As a result, for example, progress of peeling of the dicing tape can be stopped in the vicinity of the side surface of the first substrate.

Furthermore, the light emitting device of the first aspect may further include a modified layer provided on a side surface of the first substrate. As a result, for example, it is possible to suppress light from entering and exiting from the side surface of the first substrate.

Furthermore, in this first aspect, the film may include an antireflection film provided on the lens. As a result, for example, a portion in contact with the dicing tape can be the antireflection film.

Furthermore, in the first aspect, the film may include an antireflection film provided on the lens, and include a light absorption film, an inorganic film, or an organic film different from the antireflection film. As a result, for example, the structure body described above can have functions such as light absorbency, rigidity, and elasticity.

Furthermore, in the first aspect, the light absorbing film, the inorganic film, or the organic film may be provided on the antireflection film. As a result, for example, the antireflection film and the light absorbing film, the inorganic film, or the organic film can be sequentially provided on the first substrate.

Furthermore, in the first aspect, the first substrate may be a semiconductor substrate containing gallium (Ga) and arsenic (As). As a result, for example, the first substrate can be made suitable for the light emitting element.

Furthermore, in the first aspect, light emitted from the light emitting element may pass through the first substrate from the lower surface to the upper surface of the first substrate, and enters the lens. As a result, for example, the light emitting device can be a back-side emission type.

Furthermore, the light emitting device of the first aspect may further include a second substrate on which the first substrate is mounted with the light emitting element interposed therebetween. As a result, for example, a circuit for the light emitting device can be provided on the second substrate different from the first substrate.

Furthermore, in the first aspect, the second substrate may be a semiconductor substrate containing silicon (Si). As a result, for example, it is possible to form a circuit for the light emitting device on an inexpensive Si substrate while forming the light emitting element and the lens on a highly characteristic GaAs substrate.

A light emitting device according to a second aspect of the present disclosure includes: a first substrate; a light emitting element provided on a lower surface of the first substrate; a lens provided on an upper surface of the first substrate and having a convex shape or a concave shape; and a structure body that is provided on the upper surface of the first substrate, has a protruding shape or a recessed shape, and is different from the lens, in which, in a case where the lens has a convex shape, the structure body has a protruding shape, and a height of an uppermost portion of the lens is higher than a height of an uppermost portion of the structure body, or the structure body has a recessed shape, and in a case where the lens has a concave shape, the structure body has a recessed shape. As a result, it is possible to provide the light emitting element on the first substrate in a suitable state. For example, by stopping progress of peeling of the dicing tape by using this structure body, it is possible to suppress adhesion of the adhesive material of the dicing tape to the first substrate, whereby a state of the first substrate can be favorably maintained.

A distance measuring device according to a third aspect of the present disclosure includes: a light emitting unit including a light emitting element that generates light, and configured to irradiate a subject with light from the light emitting element; a light receiving unit configured to receive light reflected from the subject; and a distance measuring unit configured to measure a distance to the subject on the basis of light received by the light receiving unit, in which the light emitting unit includes: a first substrate; the light emitting element provided on a lower surface of the first substrate; a lens provided on an upper surface of the first substrate and having a convex shape or a concave shape; a structure body that is provided on the upper surface of the first substrate, has a protruding shape or a recessed shape, and is different from the lens; and a film provided on the upper surface of the first substrate, the film including a first portion disposed on the lens or forming the lens, and a second portion disposed on the structure body or forming the structure body, in a case where the lens has a convex shape, the structure body has a protruding shape, and a height of an uppermost portion of the first portion is higher than a height of an uppermost portion of the second portion, or the structure body has a recessed shape, and in a case where the lens has a concave shape, the structure body has a recessed shape. As a result, as described above, it, it is possible to provide the light emitting element on the first substrate in a suitable state.

A distance measuring device according to a fourth aspect of the present disclosure includes: a light emitting unit including a light emitting element that generates light, and configured to irradiate a subject with light from the light emitting element; a light receiving unit configured to receive light reflected from the subject; and a distance measuring unit configured to measure a distance to the subject on the basis of light received by the light receiving unit, in which the light emitting unit includes: a first substrate; the light emitting element provided on a lower surface of the first substrate; a lens provided on an upper surface of the first substrate and having a convex shape or a concave shape; and a structure body that is provided on the upper surface of the first substrate, has a protruding shape or a recessed shape, and is different from the lens, in a case where the lens has a convex shape, the structure body has a protruding shape, and a height of an uppermost portion of the lens is higher than a height of an uppermost portion of the structure body, or the structure body has a recessed shape, and in a case where the lens has a concave shape, the structure body has a recessed shape. As a result, as described above, it, it is possible to provide the light emitting element on the first substrate in a suitable state.

### BRIEF DESCRIPTION OF DRAWINGS

FIG. 1 is a block diagram illustrating a configuration example of a distance measuring device of a first embodiment.

FIG. 2 is a diagram for explaining a structured light (STL) method of the first embodiment.

FIG. 3 is a cross-sectional view illustrating an example of a structure of a light emitting device of the first embodiment.

FIG. 4 is a cross-sectional view illustrating a structure of the light emitting device illustrated in B of FIG. 3.

FIG. 5 is a cross-sectional view and a plan view illustrating a structure of the light emitting device of the first embodiment.

FIG. 6 is a plan view and a cross-sectional view illustrating a structure of a substrate of a light emitting device of a comparative example.

FIG. 7 is a plan view and a cross-sectional view illustrating a structure of a substrate of the light emitting device of the first embodiment.

FIG. 8 is a cross-sectional view illustrating a manufacturing method for the light emitting device of the comparative example.

FIG. 9 is a cross-sectional view illustrating a manufacturing method for the light emitting device of the first embodiment.

FIG. 10 is a plan view for explaining disadvantages of the manufacturing method for the light emitting device of the comparative example.

FIG. 11 is a cross-sectional view for explaining advantages of the manufacturing method for the light emitting device of the first embodiment.

FIG. 12 is a plan view illustrating a structure of a light emitting device of a modification of the first embodiment.

FIG. 13 is a plan view and a cross-sectional view illustrating a structure of a substrate of a light emitting device of a second embodiment.

FIG. 14 is a plan view and a cross-sectional view illustrating a structure of a substrate of a light emitting device of a third embodiment.

FIG. 15 is a plan view and a cross-sectional view illustrating a structure of a substrate of a light emitting device of a fourth embodiment.

FIG. 16 is a cross-sectional view (1/4) illustrating an example of a structure of a light emitting device of a fifth embodiment.

FIG. 17 is a cross-sectional view (2/4) illustrating an example of the structure of the light emitting device of the fifth embodiment.

FIG. 18 is a cross-sectional view (3/4) illustrating an example of the structure of the light emitting device of the fifth embodiment.

FIG. 19 is a cross-sectional view (4/4) illustrating an example of the structure of the light emitting device of the fifth embodiment.

FIG. 20 is a cross-sectional view (1/2) illustrating an example of a structure of a substrate of a light emitting device of a sixth embodiment.

FIG. 21 is a cross-sectional view (2/2) illustrating an example of the structure of the substrate of the light emitting device of the sixth embodiment.

FIG. 22 is a cross-sectional view illustrating a manufacturing method for a light emitting device of a seventh embodiment.

FIG. 23 is a cross-sectional view illustrating a manufacturing method for a light emitting device of an eighth embodiment.

FIG. 24 is a cross-sectional view and a plan view illustrating a structure of a light emitting device of a ninth embodiment.

FIG. 25 is a cross-sectional view illustrating a manufacturing method for a light emitting device of a tenth embodiment.

### MODE FOR CARRYING OUT THE INVENTION

Hereinafter, embodiments of the present disclosure are described below with reference to the drawings.

### First Embodiment

### (1) Distance Measuring Device 101 of First Embodiment

### (1.1) Configuration of Distance Measuring Device 101

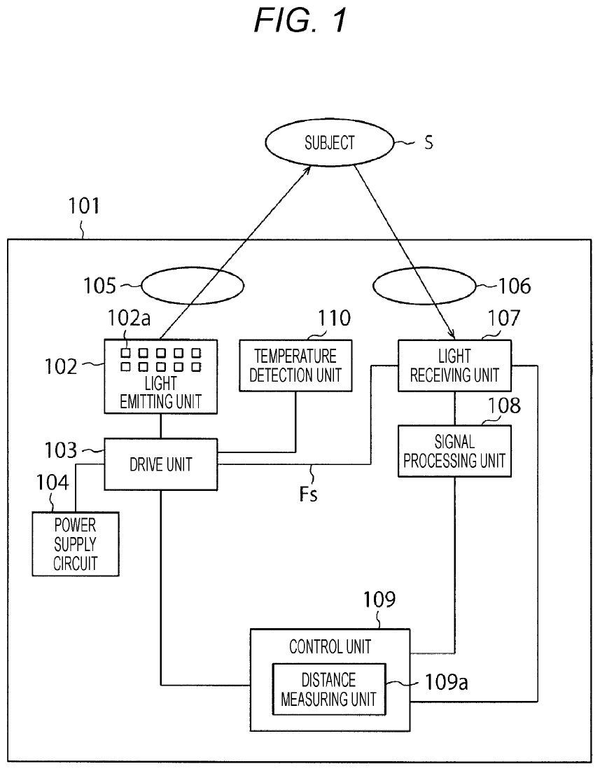

FIG. 1 is a block diagram illustrating a configuration example of a distance measuring device 101 of a first embodiment.

As illustrated in the drawing, the distance measuring device 101 includes a light emitting unit 102, a drive unit 103, a power supply circuit 104, a light-emitting side optical system 105, a light-receiving side optical system 106, a light receiving unit 107, a signal processing unit 108, a control unit 109, and a temperature detection unit 110.

The light emitting unit 102 emits light by multiple light sources. The light emitting unit 102 of the present example has a light emitting element 102a by a vertical cavity surface emitting laser (VCSEL) as each light source, and these light emitting elements 102a are disposed in a predetermined mode such as a matrix.

The drive unit 103 includes a power supply circuit for driving the light emitting unit 102.

The power supply circuit 104 generates a power supply voltage of the drive unit 103 on the basis of, for example, an input voltage from a battery or the like (not illustrated) provided in the distance measuring device 101. The drive unit 103 drives the light emitting unit 102 on the basis of the power supply voltage.

A subject S as a distance measurement target is irradiated with the light emitted from the light emitting unit 102 via the light-emitting side optical system 105. Then, the reflected light from the subject S of the light radiated in this manner is incident on the light receiving surface of the light receiving unit 107 via the light-receiving side optical system 106.

The light receiving unit 107 is, for example, a light receiving element such as a charge coupled device (CCD) sensor or a complementary metal oxide semiconductor (CMOS) sensor, receives reflected light from the subject S incident through the light-receiving side optical system 106 as described above, converts the reflected light into an electrical signal, and outputs the electrical signal.

The light receiving unit 107 executes, for example, correlated double sampling (CDS) processing, automatic gain control (AGC) processing, and the like on an electrical signal obtained by photoelectrically converting received light, and further performs analog/digital (A/D) conversion processing. Then, the signal as digital data is output to the signal processing unit 108 in the subsequent stage.

Furthermore, the light receiving unit 107 of the present example outputs a frame synchronization signal Fs to the drive unit 103. Thus, the drive unit 103 can cause the light emitting elements 102a in the light emitting unit 102 to emit light at timing corresponding to the frame period of the light receiving unit 107.

The signal processing unit 108 is configured as a signal processing processor by, for example, a digital signal processor (DSP) or the like. The signal processing unit 108 performs various types of signal processing on the digital signal input from the light receiving unit 107.

The control unit 109 includes, for example, a microcomputer including a central processing unit (CPU), a read only memory (ROM), a random access memory (RAM), and the like, or an information processing device such as a DSP, and performs control of the drive unit 103 for controlling light emission operation by the light emitting unit 102 and control related to light reception operation by the light receiving unit 107.

The control unit 109 has a function as a distance measuring unit 109a. The distance measuring unit 109a measures the distance to the subject S on the basis of a signal input via the signal processing unit 108 (that is, a signal obtained by receiving reflected light from the subject S). The distance measuring unit 109a of the present example measures the distance for each part of the subject S in order to enable identification of the three-dimensional shape of the subject S.

Here, a specific method for distance measurement in the distance measuring device 101 will be described again later.

The temperature detection unit 110 detects the temperature of the light emitting unit 102. As the temperature detection unit 110, for example, a configuration in which temperature detection is performed using a diode can be adopted.

In the present example, the information on the temperature detected by the temperature detection unit 110 is supplied to the drive unit 103, whereby the drive unit 103 can drive the light emitting unit 102 on the basis of the information on the temperature.

### (1.2) Distance Measuring Method

As a distance measuring method in the distance measuring device 101, for example, a distance measuring method by a structured light (STL) method or a time of flight (ToF) method can be adopted.

The STL method is a method for measuring a distance on the basis of an image of the subject S irradiated with light having a predetermined light/dark pattern such as a dot pattern or a lattice pattern.

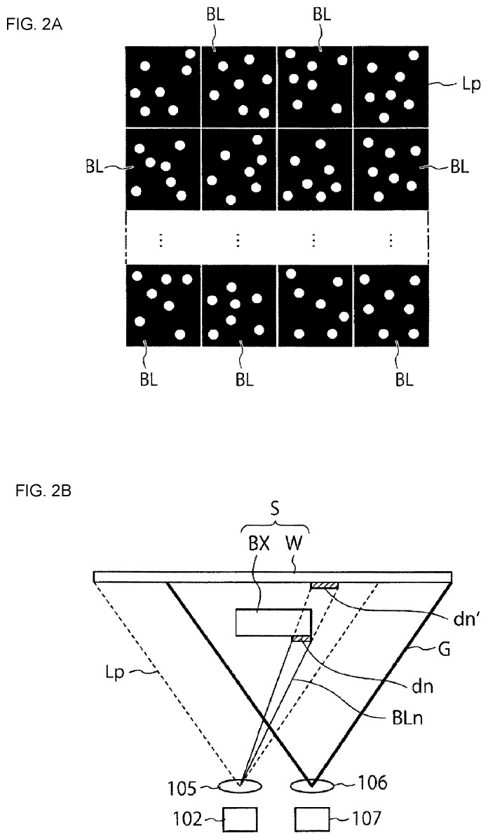

FIG. 2 is a diagram for explaining the STL method of the first embodiment.

In the STL method, for example, the subject S is irradiated with pattern light Lp by a dot pattern as illustrated in A of FIG. 2. The pattern light Lp is divided into multiple blocks BL, and different dot patterns are allocated to the respective blocks BL (the dot patterns do not overlap between the blocks B).

B of FIG. 2 is an explanatory diagram of the distance measurement principle of the STL method.

Here, an example in which a wall W and a box BX disposed in front of the wall W are the subject S, and the subject S is irradiated with the pattern light Lp is used. “G” in the drawing schematically represents the angle of view by the light receiving unit 107.

Furthermore, “BLn” in the drawing means light of a certain block BL in the pattern light Lp, and “dn” means a dot pattern of a block BLn projected on the light receiving image by the light receiving unit 107.

Here, in a case where the box BX in front of the wall W does not exist, the dot pattern of the block BLn is projected at the position of “dn′” in the drawing in the light receiving image. That is, the position at which the pattern of the block BLn is projected in the light receiving image is different between the case where the box BX exists and the case where the box BX does not exist, and specifically, the pattern distortion occurs.

The STL method is a method for obtaining the shape and depth of the subject S by using the fact that the pattern irradiated in this manner is distorted by the object shape of the subject S. Specifically, the STL method is a method for obtaining the shape and depth of the subject S from the way of the distortion of the pattern.

In the case of adopting the STL method, for example, an infrared (IR) light receiving unit by a global shutter method is used as the light receiving unit 107. Then, in the case of the STL method, the distance measuring unit 109a controls the drive unit 103 so that the light emitting unit 102 emits pattern light, detects the distortion of the pattern for the image signal obtained via the signal processing unit 108, and calculates the distance on the basis of the distortion of the pattern.

Subsequently, the ToF method is a method for measuring a distance to an object by detecting a flight time (time difference) of light emitted from the light emitting unit 102 until the light is reflected by the object and reaches the light receiving unit 107.

In a case where a so-called direct ToF (dTOF) method is adopted as the ToF method, a single photon avalanche diode (SPAD) is used as the light receiving unit 107, and the light emitting unit 102 is pulse-driven. In this case, the distance measuring unit 109a calculates a time difference between light emission and light reception for light emitted from the light emitting unit 102 and received by the light receiving unit 107 on the basis of a signal input via the signal processing unit 108, and calculates a distance to each unit of the subject S on the basis of the time difference and the speed of light.

Note that, in a case where a so-called indirect ToF (iTOF) method (phase difference method) is adopted as the ToF method, for example, a light receiving unit capable of receiving IR is used as the light receiving unit 107.

### (2) Light Emitting Device 1 of First Embodiment

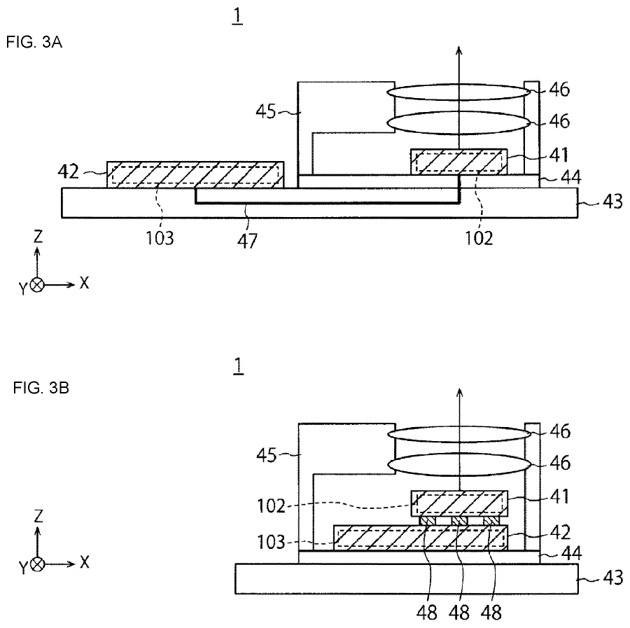

FIG. 3 is a cross-sectional view illustrating an example of a structure of a light emitting device 1 of the first embodiment. The light emitting device 1 of the present embodiment may be a part of the distance measuring device 101 or may be the distance measuring device 101 itself.

A of FIG. 3 illustrates a first example of the structure of the light emitting device 1 of the present embodiment. The light emitting device 1 of this example includes a laser diode (LD) chip 41 including the light emitting unit 102, a laser diode driver (LDD) substrate 42 including the drive unit 103, a mounting substrate 43, a heat dissipation substrate 44, a correction lens holding unit 45, one or more correction lenses 46, and wiring 47.

A of FIG. 3 illustrates an X axis, a Y axis, and a Z axis perpendicular to each other. An X direction and a Y direction correspond to a lateral direction (horizontal direction), and a Z direction corresponds to a longitudinal direction (vertical direction). In addition, a +Z direction corresponds to an upward direction, and a −Z direction corresponds to a downward direction. The −Z direction may strictly match the gravity direction, or does not necessarily strictly match the gravity direction.

The LD chip 41 is disposed on the mounting substrate 43 with the heat dissipation substrate 44 interposed therebetween, and the LDD substrate 42 is also disposed on the mounting substrate 43. The mounting substrate 43 is, for example, a printed board. On the mounting substrate 43, the light receiving unit 107 and the signal processing unit 108 illustrated in FIG. 1 may further be disposed. The heat dissipation substrate 44 is, for example, a ceramic substrate such as an Al₂O₃ (aluminum oxide) substrate or an AlN (aluminum nitride substrate).

The correction lens holding unit 45 is disposed on the heat dissipation substrate 44 so as to surround the LD chip 41, and holds one or more of correction lenses 46 above the LD chip 41. These correction lenses 46 are included in the above-described light-emitting side optical system 105. The light emitted from the light emitting unit 102 in the LD chip 41 is corrected by these correction lenses 46 and then radiated to the subject S. A of FIG. 3 illustrates two correction lenses 46 held by the correction lens holding unit 45 as an example.

The wiring 47 is provided on the front surface, the back surface, the inside, or the like of the mounting substrate 43, and electrically connects the LD chip 41 and the LDD substrate 42. The wiring 47 is, for example, printed wiring provided on the front surface or the back surface of the mounting substrate 43 or via wiring penetrating the mounting substrate 43. The wiring 47 of the present embodiment further passes through the inside or the vicinity of the heat dissipation substrate 44.

B of FIG. 3 illustrates a second example of the structure of the light emitting device 1 of the present embodiment. The light emitting device 1 of the present example includes the same components as those of the light emitting device 1 of the first example, but includes bumps 48 instead of the wiring 47.

In B of FIG. 3, the LDD substrate 42 is disposed on the heat dissipation substrate 44, and the LD chip 41 is disposed on the LDD substrate 42. By arranging the LD chip 41 on the LDD substrate 42 in this manner, the size of the mounting substrate 43 can be reduced as compared with the case of the first example. In B of FIG. 3, the LD chip 41 is disposed on the LDD substrate 42 with the bumps 48 interposed therebetween, and is electrically connected to the LDD substrate 42 by the bumps 48. The bumps 48 are constituted by, for example, gold (Au).

Hereinafter, the light emitting device 1 of the present embodiment will be described as having the structure of the second example illustrated in B of FIG. 3. However, the following description is also applicable to the light emitting device 1 having the structure of the first example except for the description of the structure specific to the second example.

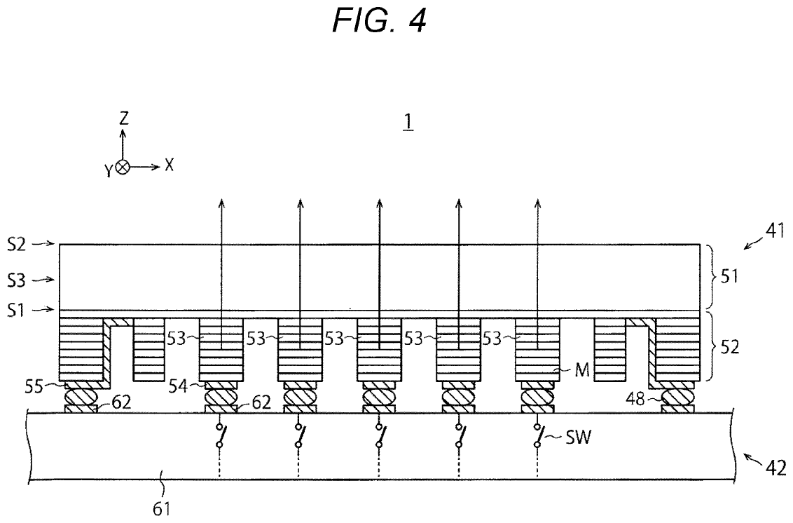

FIG. 4 is a cross-sectional view illustrating a structure of the light emitting device 1 illustrated in B of FIG. 3.

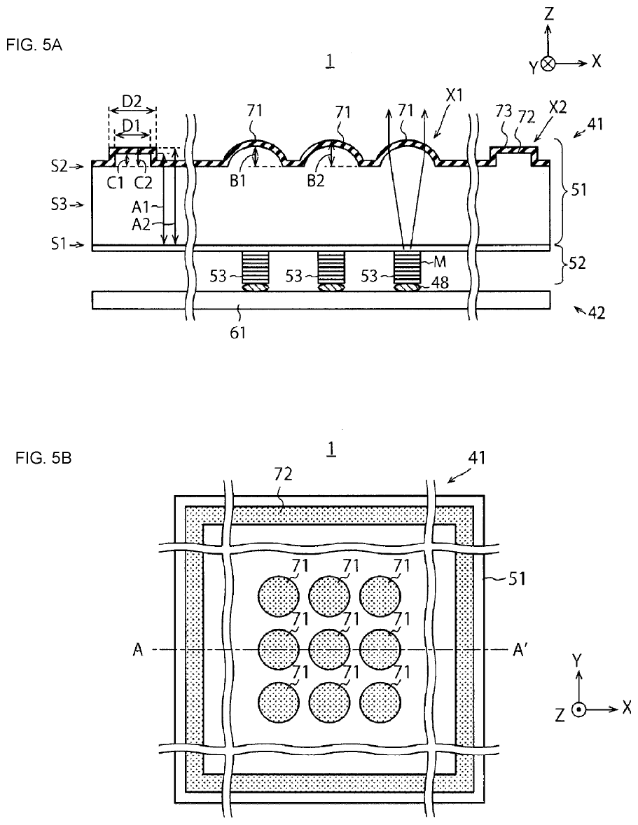

FIG. 4 illustrates cross sections of the LD chip 41 and the LDD substrate 42 in the light emitting device 1. As illustrated in FIG. 4, the LD chip 41 includes a substrate 51, a laminated film 52, multiple light emitting elements 53, multiple anode electrodes 54, and multiple cathode electrodes 55, and the LDD substrate 42 includes a substrate 61 and multiple connection pads 62. The substrate 51 is an example of a first substrate of the present disclosure, and the substrate 61 is an example of a second substrate of the present disclosure. The light emitting element 53 illustrated in FIG. 4 is a specific example of the light emitting element 102a described above. Note that, in FIG. 4, illustration of a lens 71, a structure body 72, and an antireflection film 73 to be described later is omitted (see FIG. 5).

The substrate 51 is, for example, a compound semiconductor substrate such as a GaAs (gallium arsenide) substrate. FIG. 4 illustrates a front surface S1 of the substrate 51 facing the −Z direction, a back surface S2 of the substrate 51 facing the +Z direction, and multiple side surfaces S3 of the substrate 51 provided between the front surface S1 and the back surface S2. The front surface S1 and the back surface S2 illustrated in FIG. 4 are perpendicular to the Z direction. In FIG. 4, the front surface S1 is a lower surface of the substrate 51, and the back surface S2 is an upper surface of the substrate 51.

The laminated film 52 includes multiple layers laminated on the front surface S1 of the substrate 51. Examples of these layers include an n-type semiconductor layer, an active layer, a p-type semiconductor layer, a light reflecting layer, and an insulating layer having a light emission window. The laminated film 52 includes multiple mesa portions M protruding in the-z direction. Parts of these mesa portions M are the multiple light emitting elements 53.

The light emitting elements 53 are provided on the front surface S1 of the substrate 51 as parts of the laminated film 52. The light emitting elements 53 of the present embodiment have a VCSEL structure and emit light in the +Z direction. As illustrated in FIG. 4, the light emitted from the light emitting elements 53 passes through the substrate 51 from the front surface S1 to the back surface S2 of the substrate 51, and enters the above-described correction lenses 46 (FIG. 3) from the substrate 51. In this way, the LD chip 41 of the present embodiment is a back-side emission type VCSEL chip.

The anode electrodes 54 are formed on lower surfaces of the light emitting elements 53. The cathode electrodes 55 are formed on lower surfaces of the mesa portions M other than the light emitting elements 53, and extends from the lower surfaces of the mesa portions M to a lower surface of the laminated film 52 between the mesa portions M. Each light emitting element 53 emits light when a current flows between the corresponding anode electrode 54 and the corresponding cathode electrode 55.

As described above, the LD chip 41 is disposed on the LDD substrate 42 with the bumps 48 interposed therebetween, and is electrically connected to the LDD substrate 42 by the bumps 48. Specifically, the connection pads 62 are formed on the substrate 61 included in the LDD substrate 42, and the mesa portions M are disposed on the connection pads 62 with the bumps 48 interposed therebetween. Each mesa portion M is disposed on the bump 48 via the anode electrode 54 or the cathode electrode 55. The substrate 61 is, for example, a semiconductor substrate such as a silicon (Si) substrate.

The LDD substrate 42 includes the drive unit 103 that drives the light emitting unit 102. FIG. 4 schematically illustrates multiple switches SW included in the drive unit 103. Each switch SW is electrically connected to the corresponding light emitting element 53 via the bump 48. The drive unit 103 of the present embodiment can control (turn on and off) these switches SW for each switch SW. Therefore, the drive unit 103 can drive the multiple light emitting elements 53 for every light emitting element 53. As a result, it is possible to precisely control the light emitted from the light emitting unit 102, for example, by causing only the light emitting elements 53 necessary for distance measurement to emit light. Such individual control of the light emitting elements 53 can be implemented by arranging the LDD substrate 42 below the LD chip 41, so that each light emitting element 53 is easily electrically connected to the corresponding switch SW.

FIG. 5 is a cross-sectional view and a plan view illustrating a structure of the light emitting device 1 of the first embodiment.

A of FIG. 5 illustrates cross sections of the LD chip 41 and the LDD substrate 42 in the light emitting device 1. As described above, the LD chip 41 includes the substrate 51, the laminated film 52, the multiple light emitting elements 53, the multiple anode electrodes 54, and the multiple cathode electrodes 55, and the LDD substrate 42 includes the substrate 61 and the multiple connection pads 62. However, in A of FIG. 5, illustration of the anode electrodes 54, the cathode electrodes 55, and the connection pads 62 is omitted.

The LD chip 41 of the present embodiment includes the multiple light emitting elements 53 on the front surface S1 of the substrate 51, and multiple lenses 71, the structure body 72, and the antireflection film 73 on the back surface S2 of the substrate 51. The antireflection film 73 is an example of a film of the present disclosure.

Similarly to the light emitting elements 53, the lenses 71 are arranged in a two-dimensional array. The lenses 71 of the present embodiment correspond to the light emitting elements 53 on a one-to-one basis, and each of the lenses 71 is disposed in the +Z direction of one light emitting element 53. Furthermore, as illustrated in A of FIG. 5, the lenses 71 of the present embodiment are provided as parts of the substrate 51 on the back surface S2 of the substrate 51. Specifically, the lenses 71 of the present embodiment are convex lenses, and are formed as parts of the substrate 51 by etching processing of the back surface S2 of the substrate 51 into convex shapes. According to the present embodiment, by forming the lenses 71 by etching processing of the substrate 51, the lenses 71 can be easily formed. Note that details of an example of the lens 71 other than the convex lens and etching processing of the substrate 51 for forming the lens 71 will be described later.

The structure body 72 is provided on the back surface S2 of the substrate 51, and forms a step on the back surface S2 of the substrate 51. The structure body 72 of the present embodiment has a protruding shape similarly to the lens 71 that is a convex lens, but is not used as the lens 71. As will be described later, the structure body 72 of the present embodiment has a shape annularly surrounding all the lenses 71 on the substrate 51 (see B of FIG. 5). Furthermore, similarly to the lenses 71, the structure body 72 of the present embodiment is provided as a part of the substrate 51 on the back surface S2 of the substrate 51. Therefore, according to the present embodiment, by forming the structure body 72 by etching processing of the substrate 51, the structure body 72 can be easily formed. Note that details of an example of the structure body 72 having a shape other than the protruding shape and the etching processing of the substrate 51 for forming the structure body 72 will be described later.

The antireflection film 73 is provided on the back surface S2 of the substrate 51 so as to cover the lenses 71 and the structure body 72. Therefore, the antireflection film 73 includes a first portion X1 disposed on the lenses 71 and a second portion X2 disposed on the structure body 72. The antireflection film 73 has a function of preventing light incident on the lenses 71 from the inside of the substrate 51 from being reflected to the inside of the substrate 51. The antireflection film 73 is, for example, a silicon oxide film. The antireflection film 73 has a uniform thickness in the present embodiment, but may have a non-uniform thickness.

The light emitted from the multiple light emitting elements 53 described above is transmitted through the substrate 51 from the front surface SI to the back surface S2 of the substrate 51, and enters the multiple lenses 71 described above. In the present embodiment, the light emitted from each light emitting element 53 is incident on one corresponding lens 71. As a result, the light emitted from the multiple light emitting elements 53 described above can be molded for each lens 71. The light having passed through the multiple lenses 71 described above passes through the correction lenses 46 (FIG. 3) and is radiated to the subject S (FIG. 1). Note that an example of a case where the light emitting elements 53 and the lenses 71 do not correspond to each other on a one-to-one basis will be described later.

Here, thicknesses A1, A2, B1, B2, C1, and C2 and widths D1 and D2 illustrated in A of FIG. 5 will be described.

In the present embodiment, a height of an uppermost portion of each lens 71 is higher than a height of an uppermost portion of the structure body 72. In other words, the Z coordinate of the uppermost portion of each lens 71 is larger than the Z coordinate of the uppermost portion of the structure body 72. Since each lens 71 of the present embodiment is a convex lens, the uppermost portion of each lens 71 is a top portion of each lens 71. Whereas, since the structure body 72 of the present embodiment has a protruding shape and has a flat upper surface, the uppermost portion of the structure body 72 is an upper surface of the structure body 72. Therefore, in the present embodiment, a height of the top portion of each lens 71 is higher than a height of the upper surface of the structure body 72.

As a result, a height of an uppermost portion of the first portion X1 of the antireflection film 73 on each lens 71 is higher than a height of an uppermost portion of the second portion X2 of the antireflection film 73 on the structure body 72. The uppermost portion of the first portion X1 on each lens 71 is present above the top portion of each lens 71. Whereas, the uppermost portion of the second portion X2 on the structure body 72 is present above the upper surface of the structure body 72. Therefore, the height of the uppermost portion of the first portion X1 that is present above the top portion of each lens 71 is higher than the height of the uppermost portion of the second portion X2 that is present above the upper surface of the structure body 72.

The thicknesses A1, B1, and C1 represent thicknesses of the substrate 51, the lens 71, and the structure body 72 in the Z direction, respectively. A width D1 represents a width of the structure body 72 in the X direction in A of FIG. 5. The thickness A1 of the substrate 51 is, for example, 100 to 600 μm. The thickness B1 of the lens 71 is, for example, 0.1 to 10 μm. The thickness C1 of the structure body 72 is, for example, 0.1 to 10 μm. The width D1 of the structure body 72 is, for example, 10 to 100 μm. Furthermore, a thickness of the antireflection film 73 is, for example, 0.1 to 1 μm.

The thickness B1 of each lens 71 corresponds to the height of the uppermost portion of each lens 71 with respect to the flat portion of the back surface S2 of the substrate 51. Similarly, the thickness C1 of the structure body 72 corresponds to the height of the uppermost portion of the structure body 72 with respect to the flat portion of the back surface S2 of the substrate 51. Therefore, the fact that the height of the uppermost portion of each lens 71 is higher than the height of the uppermost portion of the structure body 72 can be rephrased that the thickness B1 of each lens 71 is thicker than the thickness C1 of the structure body 72 (B1>C1).

Moreover, the thicknesses A2, B2, and C2 represent a total thickness of the substrate 51 and the antireflection film 73, a total thickness of the lens 71 and the antireflection film 73, and a total thickness of the structure body 72 and the antireflection film 73, respectively. A width D2 represents a total width of the structure body 72 and the antireflection film 73 in A of FIG. 5. The fact that the height of the uppermost portion of the first portion X1 on each lens 71 is higher than the height of the uppermost portion of the second portion X2 on the structure body 72 can be rephrased as that the total thickness B2 of each lens 71 and the antireflection film 73 is thicker than the total thickness C2 of the structure body 72 and the antireflection film 73 (B2>C2).

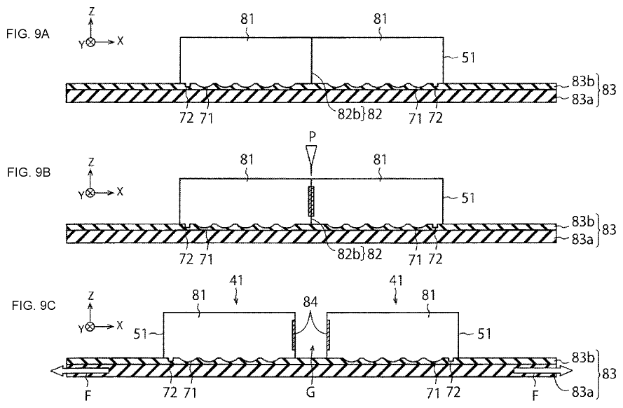

When the LD chip 41 of the present embodiment is manufactured, as described later, the light emitting element 53, the lens 71, the structure body 72, the antireflection film 73, and the like are provided on the substrate 51, and then the substrate 51 is diced. Specifically, a dicing tape is bonded to the substrate 51, the substrate 51 is irradiated with a laser, and the dicing tape is extended. As a result, the substrate 51 is divided into multiple chips (LD chips 41) (see FIG. 9).

However, when the dicing tape is extended, an adhesive material of the dicing tape may be extended, and an edge portion of the LD chip 41 may be peeled off from the dicing tape. In this case, the adhesive material of the dicing tape may be torn off near the edge portion of the LD chip 41, and the adhesive material of the dicing tape may adhere to the LD chip 41. As a result, there is a possibility that the LD chip 41 to which the adhesive material adheres becomes a defective product. In this way, when the substrate 51 is processed, a state of the substrate 51 may be deteriorated.

Therefore, when the LD chip 41 of the present embodiment is manufactured, not only the lens 71 but also the structure body 72 is provided on the substrate 51, and then the substrate 51 is diced. As a result, by stopping progress of peeling of the dicing tape by using the structure body 72, it is possible to suppress adhesion of the adhesive material of the dicing tape to the lens 71 and the like. Moreover, by setting the height of the uppermost portion of the first portion X1 on each lens 71 to be higher than the height of the uppermost portion of the second portion X2 on the structure body 72, it is possible to suppress concentration of a load when the dicing tape is bonded to the structure body 72. Accordingly, it is possible to suppress the adhesive material of the dicing tape from being fixed to the structure body 72. As a result, the state of the substrate 51 can be favorably maintained. Further details of such an action will be described later.

Note that the multiple lenses 71 described above have the same shape in the present embodiment, but may have different shapes. Furthermore, the structure body 72 has a flat upper surface in the present embodiment, but may have a non-flat upper surface. Even in these cases, the effect described above can be obtained by setting the height of the uppermost portion of the first portion X1 on each lens 71 to be higher than the height of the uppermost portion of the second portion X2 on the structure body 72.

B of FIG. 5 illustrates a layout of the lenses 71 and the structure body 72 provided on the back surface S2 of the substrate 51. In B of FIG. 5, the lenses 71 are arranged in a two-dimensional array on the back surface S2 of the substrate 51, specifically, arranged in a square lattice pattern. Furthermore, the structure body 72 has a quadrangular annular shape extending along four edges of the quadrangular back surface S2, and annularly surrounds all the lenses 71 on the substrate 51. Note that A of FIG. 5 illustrates a cross section taken along line A-A′ illustrated in B of FIG. 5.

### (3) Comparison Between Light Emitting Device 1 of First Embodiment and Light Emitting Device 1 of Comparative Example

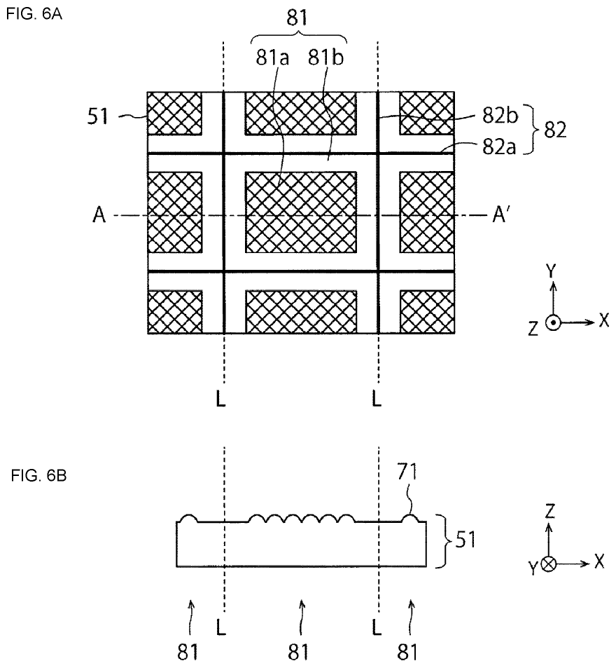

Next, with reference to FIGS. 6 to 11, the light emitting device 1 of the first embodiment is compared with a light emitting device 1 of a comparative example. In the description of the light emitting device 1 of the present comparative example, the same reference numerals as those used in the description of the light emitting device 1 of the present embodiment are used.

FIG. 6 is a plan view and a cross-sectional view illustrating a structure of a substrate 51 of the light emitting device 1 of the comparative example. A of FIG. 6 is a plan view illustrating a structure of the substrate 51 before dicing, and B of FIG. 6 is a cross-sectional view taken along line A-A′ illustrated in A of FIG. 6.

As illustrated in A and B of FIG. 6, the substrate 51 of the present comparative example includes multiple chip regions 81 and a scribe region (dicing region) 82. Each chip region 81 is a region to be one LD chip 41 after dicing of the substrate 51. The scribe region 82 is a region cut at the time of dicing the substrate 51. The substrate 51 of the present comparative example is divided into multiple chip regions 81 by being cut in the scribe region 82.

Each chip region 81 has a rectangular (or square) planar shape, and includes a lens region 81a and a peripheral region 81b. The lens region 81a includes multiple lenses 71 arranged in a two-dimensional array (B of FIG. 6). The peripheral region 81b annularly surrounds the lens region 81a.

The scribe region 82 has a planar shape annularly surrounding the multiple chip regions 81 described above for each of the chip regions 81, and includes multiple scribe lines (dicing lines) 82a extending in the X direction and multiple scribe lines 82b extending in the Y direction. The substrate 51 of the present comparative example is divided into the multiple chip regions 81 by being cut by applying a dicer to these scribe lines 82a and 82b. A reference sign L indicates planes passing through the scribe lines 82b.

It should be noted that the structure body 72 is not provided on the substrate 51 of the present comparative example. Note that the antireflection film 73 is formed later on the substrate 51 illustrated in A and B of FIG. 6. That is, A and B of FIG. 6 illustrate the substrate 51 before the antireflection film 73 is formed.

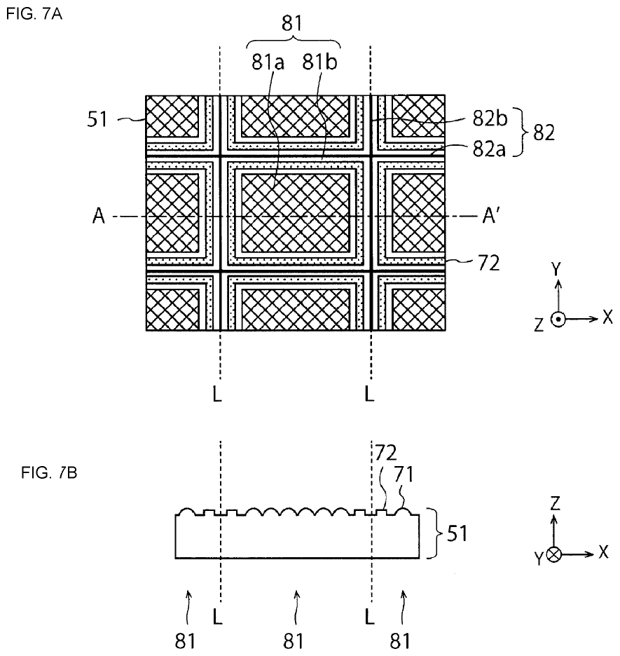

FIG. 7 is a plan view and a cross-sectional view illustrating a structure of the substrate 51 of the light emitting device 1 of the first embodiment. A of FIG. 7 is a plan view illustrating a structure of the substrate 51 before dicing, and B of FIG. 7 is a cross-sectional view taken along line A-A′ illustrated in A of FIG. 7.

As illustrated in A and B of FIG. 7, the substrate 51 of the present embodiment includes the multiple chip regions 81 and the scribe region 82. The structure of the chip regions 81 and the scribe region 82 of the present embodiment is substantially the same as the structure of the chip regions 81 and the scribe region 82 of the comparative example.

However, the substrate 51 of the present embodiment is provided with multiple structure bodies 72. These structure bodies 72 are provided in the chip regions 81 of the substrate 51, and specifically, one structure body 72 is provided in one chip region 81 (A of FIG. 7). Each structure body 72 is provided in a peripheral region 81b and has a planar shape annularly surrounding a lens region 81a. It should be noted that each structure body 72 of the present embodiment is not provided in the scribe region 82, as illustrated in A and B of FIG. 7.

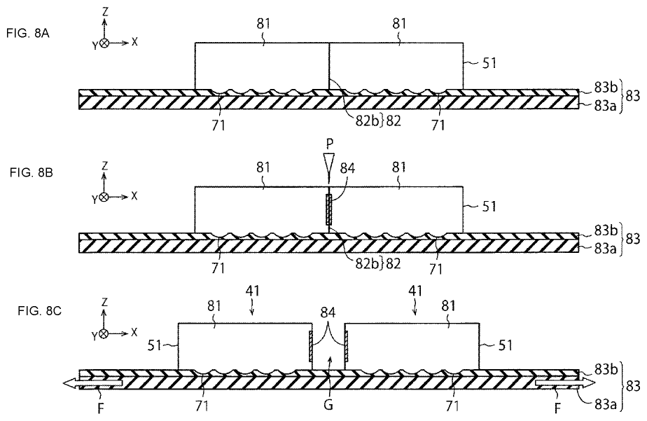

FIG. 8 is a cross-sectional view illustrating a manufacturing method for the light emitting device 1 of the comparative example. A to C of FIG. 8 illustrate a process of manufacturing a LD chip 41 of the light emitting device 1 of the present comparative example.

First, the laminated film 52, a light emitting element 53, the lenses 71, the antireflection film 73, and the like are provided on the substrate 51, and then a dicing tape 83 is bonded to the substrate 51 (A of FIG. 8). However, A of FIG. 8 illustrates the substrate 51 and the lenses 71, but illustration of the laminated film 52, the light emitting element 53, and the antireflection film 73 is omitted. In A of FIG. 8, a front surface S1 of the substrate 51 is an upper surface of the substrate 51, and a back surface S2 of the substrate 51 is a lower surface of the substrate 51. A of FIG. 8 further illustrates the chip region 81 and the scribe region 82 of the substrate 51.

As illustrated in A of FIG. 8, the dicing tape 83 includes a base material 83a and an adhesive material 83b provided on the base material 83a. The substrate 51 of the present comparative example is bonded to the dicing tape 83 such that the lenses 71 and the adhesive material 83b are in contact with each other. The process illustrated in A of FIG. 8 is referred to as a laminating process of the dicing tape 83.

Next, the substrate 51 is irradiated with a laser beam (B of FIG. 8). A reference sign P indicates a stealth laser beam with which the substrate 51 is irradiated. The scribe region 82 of the substrate 51 is irradiated with the laser beam of the present comparative example. As a result, the substrate 51 is modified by the laser beam in the scribe region 82, and a modified layer 84 is formed in the scribe region 82.

Next, in a state where the dicing tape 83 is bonded to the substrate 51, the dicing tape 83 is extended as indicated by arrows F (C of FIG. 8). As a result, a force is applied from the dicing tape 83 to the substrate 51, and the substrate 51 is divided for every chip region 81 (for every LD chip 41). This is because the modified layer 84 in the substrate 51 is more easily cracked than other portions in the substrate 51. The process illustrated in C of FIG. 8 is referred to as an expanding process of the dicing tape 83. A reference sign G indicates a gap generated between the LD chips 41 due to the division of the substrate 51.

In the present comparative example, when the dicing tape 83 is extended in the expanding process, there is a possibility that the adhesive material 83b of the dicing tape 83 is extended and an edge portion of the LD chip 41 is peeled off from the dicing tape 83. In this case, the adhesive material 83b of the dicing tape 83 may be torn off near the edge portion of the LD chip 41, and the adhesive material 83b of the dicing tape 83 may adhere to the LD chip 41. As a result, there is a possibility that the LD chip 41 to which the adhesive material 83b adheres becomes a defective product. In this way, when the substrate 51 is processed, a state of the substrate 51 may be deteriorated.

FIG. 9 is a cross-sectional view illustrating a manufacturing method for the light emitting device 1 of the first embodiment. A to C of FIG. 9 illustrate a process of manufacturing the LD chip 41 of the light emitting device 1 of the present embodiment. In the description of A to C of FIG. 9, a description of matters common to the description of A to C of FIG. 8 will be appropriately omitted.

First, the laminated film 52, the light emitting element 53, the lens 71, the structure body 72, the antireflection film 73, and the like are provided on the substrate 51, and then the dicing tape 83 is bonded to the substrate 51 (A of FIG. 9). However, A of FIG. 9 illustrates the substrate 51, the lens 71, and the structure body 72, but illustration of the laminated film 52, the light emitting element 53, and the antireflection film 73 is omitted.

Next, the substrate 51 is irradiated with a laser beam (B of FIG. 9). The scribe region 82 of the substrate 51 is also irradiated with the laser beam of the present embodiment. As a result, the modified layer 84 is formed in the scribe region 82.

Next, in a state where the dicing tape 83 is bonded to the substrate 51, the dicing tape 83 is extended as indicated by arrows F (C of FIG. 9). As a result, the substrate 51 is divided for every chip region 81 (for every LD chip 41).

In the present embodiment, the substrate 51 is diced after not only the lens 71 but also the structure body 72 is provided on the substrate 51. As a result, by stopping progress of peeling of the dicing tape 83 by using the structure body 72, it is possible to suppress adhesion of the adhesive material 83b of the dicing tape 83 to the lens 71 and the like. Furthermore, by setting the height of the uppermost portion of the first portion X1 on each lens 71 to be higher than the height of the uppermost portion of the second portion X2 on the structure body 72 (see A of FIG. 5), it is possible to suppress concentration of a load when the dicing tape 83 is bonded to on the structure body 72. As a result, it is possible to suppress the adhesive material 83b of the dicing tape 83 from being fixed to the structure body 72. As a result, the state of the substrate 51 can be favorably maintained.

C of FIG. 9 illustrates the modified layer 84 remaining on the side surface S3 of the substrate 51 after dicing. In the substrate 51 after dicing, the side surface S3 of the substrate 51 is coarser than another surface of the substrate 51 due to an influence of the modified layer 84. In other words, the side surface S3 of the substrate 51 after dicing has large roughness. In the present embodiment, the side surface S3 of the substrate 51 after dicing may be planarized by polishing, or may be left rough without being polished. In the latter case, since the side surface S3 of the substrate 51 is rough, it is possible to suppress light from entering and exiting from the side surface S3 of the substrate 51. The side surface S3 of the substrate 51 after dicing includes, for example, multiple concave portions having a size of 1 to 3 μm due to the influence of the modified layer 84, and these concave portions roughen the side surface S3 of the substrate 51.

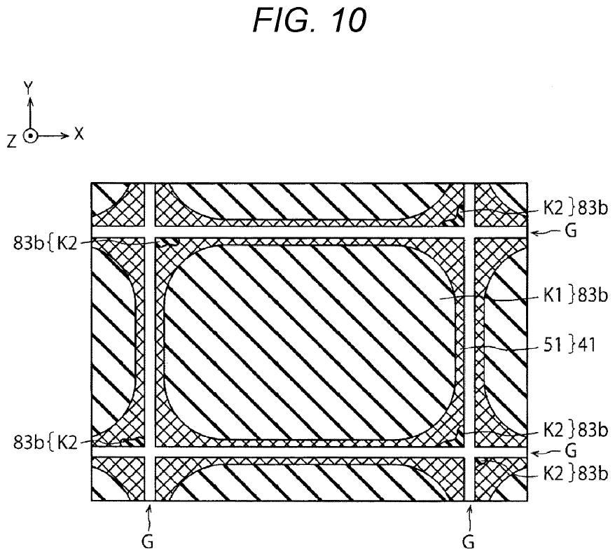

FIG. 10 is a plan view for explaining disadvantages of a manufacturing method for the light emitting device 1 of the comparative example.

FIG. 10 illustrates a state in which the back surface S2 of the substrate 51 is observed through the dicing tape 83 after the substrate 51 is divided in C of FIG. 8. Specifically, FIG. 10 illustrates the back surface S2 of the substrate 51 in nine LD chips 41 and the gap G between these LD chips 41.

FIG. 10 further illustrates a state in which the adhesive material 83b is present on the back surface S2 of the substrate 51 after dicing. In FIG. 10, a region indicated by cross hatching indicates a region where the adhesive material 83b is not present, and a region indicated by oblique hatching indicates a region where the adhesive material 83b is present. Furthermore, reference numeral K1 denotes the adhesive material 83b present near a central portion of the LD chip 41, and reference numeral K2 denotes the adhesive material 83b present near an edge portion of the LD chip 41.

As described above, when the dicing tape 83 is extended in the expanding process, there is a possibility that the adhesive material 83b of the dicing tape 83 is extended and an edge portion of the LD chip 41 is peeled off from the dicing tape 83. A region indicated by cross hatching in FIG. 10 corresponds to a region where such peeling has occurred. In this case, the adhesive material 83b of the dicing tape 83 may be torn off near the edge portion of the LD chip 41, and the adhesive material 83b of the dicing tape 83 may adhere to the LD chip 41. The adhesive material 83b indicated by reference sign K2 corresponds to the adhesive material 83b torn off in this manner. When the dicing tape 83 is peeled off from the diced substrate 51, the adhesive material 83b indicated by reference numeral K1 is generally peeled off from the substrate 51 together with the base material 83a, but the adhesive material 83b indicated by reference numeral K2 may remain on the substrate 51.

The adhesive material 83b attached to the LD chip 41 may deteriorate optical characteristics of the LD chip 41. For example, when the adhesive material 83b adheres to the lens 71, there is a possibility that light does not pass through the lens or is less likely to pass through the lens 71. Similarly, the adhesive material 83b attached to a region other than the lens 71 on the back surface S2 of the substrate 51 may also deteriorate the optical characteristics of the LD chip 41.

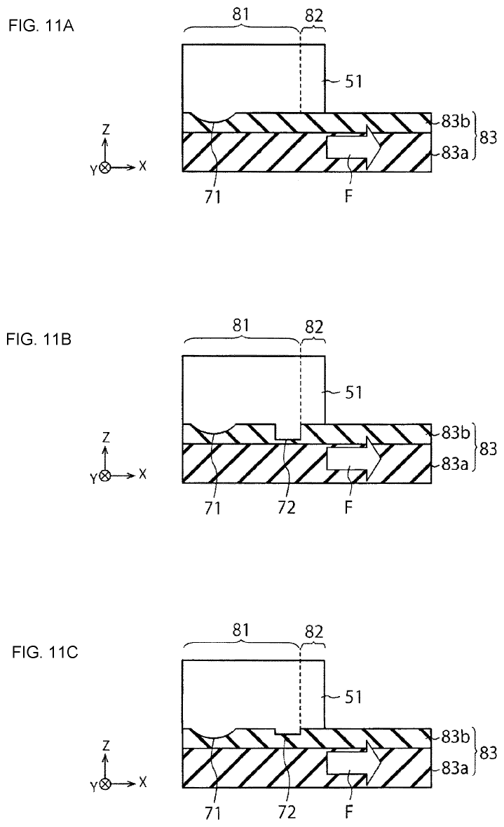

FIG. 11 is a cross-sectional view for explaining advantages of a manufacturing method for the light emitting device 1 of the first embodiment. A to C of FIG. 11 illustrate the lens 71 and the structure body 72, but illustration of the antireflection film 73 is omitted.

A of FIG. 11 illustrates the expanding process of the comparative example, similarly to C of FIG. 8. The substrate 51 of the present comparative example includes the lenses 71 but does not include the structure body 72. Therefore, when the dicing tape 83 is extended in the expanding process, the adhesive material 83b of the dicing tape 83 may be extended, and an edge portion of the LD chip 41 may be peeled off from the dicing tape 83.

B of FIG. 11 illustrates the expanding process of the present embodiment, similarly to C of FIG. 10. The substrate 51 of the present embodiment includes the lenses 71 and the structure body 72. As a result, by stopping progress of peeling of the dicing tape 83 by using the structure body 72, it is possible to suppress adhesion of the adhesive material 83b of the dicing tape 83 to the lens 71 and the like. According to the present embodiment, progress of peeling of the dicing tape 83 can be stopped by using the structure body 72 so as not to spread to the lens 71.

However, the thickness B1 (see A of FIG. 5) of the lens 71 illustrated in B of FIG. 11 is thinner than the thickness C1 of the structure body 72. Therefore, in a case where the back surface S2 of the substrate 51 faces the +Z direction as illustrated in A of FIG. 5, the height of the uppermost portion of the first portion X1 on the lens 71 is lower than the height of the uppermost portion of the second portion X2 on the structure body 72. As a result, the structure body 72 illustrated in B of FIG. 11 protrudes in the −Z direction from the lens 71. Therefore, when the dicing tape 83 is bonded to the substrate 51, a load of attaching the dicing tape 83 is concentrated on the structure body 72, and the adhesive material 83b of the dicing tape 83 may be fixed to the structure body 72.

Similarly to C of FIG. 10, C of FIG. 11 illustrates the expanding process of the present embodiment. However, the thickness B1 (see A of FIG. 5) of the lens 71 illustrated in C of FIG. 11 is thicker than the thickness C1 of the structure body 72. Therefore, in a case where the back surface S2 of the substrate 51 faces the +Z direction as illustrated in A of FIG. 5, the height of the uppermost portion of the first portion X1 on the lens 71 is higher than the height of the uppermost portion of the second portion X2 on the structure body 72. As a result, it is possible to suppress concentration of a load on the structure body 72 when the dicing tape 83 is bonded, and it is possible to suppress the adhesive material 83b of the dicing tape 83 from being fixed to the structure body 72. Therefore, in a case where the structure body 72 is provided on the substrate 51, the thickness B1 of the lens 71 is desirably thicker than the thickness C1 of the structure body 72.

Here, reference is made again to A and B of FIG. 5.

A of FIG. 5 illustrates the side surface S3 of the substrate 51. In the present embodiment, it is desirable to set a distance between the side surface S3 of the substrate 51 and the structure body 72 to be short. This is for stopping progress of peeling of the dicing tape 83 in the vicinity of the side surface S3 of the substrate 51, to narrow the region where the dicing tape 83 is peeled off. The distance between the side surface S3 of the substrate 51 and the structure body 72 is desirably set to, for example, 10 to 100 μm. Furthermore, it is desirable that peeling of the dicing tape 83 is stopped at the peripheral region 81b so as not to spread to the lens region 81a (see A of FIG. 7).

As illustrated in B of FIG. 5, the light emitting device 1 of the present embodiment includes multiple lenses 71 on the back surface S2 of the substrate 51, and the structure body 72 of the present embodiment has a shape annularly surrounding these lenses 71. According to the present embodiment, by disposing the structure body 72 in a wide range around the lens 71, progress of peeling of the dicing tape 83 can be stopped in a wide range. Note that, other examples of the shape of the structure body 72 will be described later.

### (4) Light Emitting Device 1 of Modification of First Embodiment

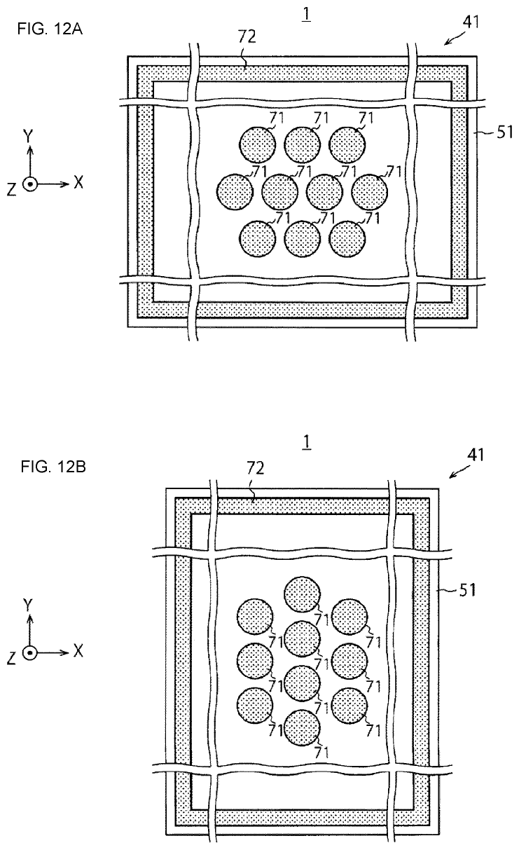

FIG. 12 is a plan view illustrating a structure of a light emitting device 1 of a modification of the first embodiment.

A of FIG. 12 illustrates a layout of the lenses 71 and the structure body 72 provided on the back surface S2 of the substrate 51, similarly to B of FIG. 5. However, the lenses 71 illustrated in B of FIG. 5 are arranged in a square lattice pattern, whereas the lenses 71 illustrated in A of FIG. 12 are arranged in a triangular lattice pattern. In this way, the layout when the lenses 71 are arranged in a two-dimensional array may be any layout.

Note that a direction of the lattice when the lenses 71 are arranged in a triangular lattice shape may be a direction illustrated in A of FIG. 12 or a direction illustrated in B of FIG. 12. Furthermore, the layout of the lenses 71 may be a regular layout such as a square lattice or a triangular lattice, or may be an irregular layout in which the lenses 71 are randomly arranged. Furthermore, the layout of the structure body 72 can also be various layouts as described later.

As described above, in the light emitting device 1 of the present embodiment, the height of the uppermost portion of the antireflection film 73 (first portion X1) on each lens 71 is higher than the height of the uppermost portion of the antireflection film 73 (second portion X2) on the structure body 72 different from the lens 71. Therefore, according to the present embodiment, the light emitting element 53 and the lens 71 can be provided on the substrate 51 in a suitable state. For example, by stopping progress of peeling of the dicing tape 83 by using the structure body 72, it is possible to suppress adhesion of the adhesive material 83b of the dicing tape 83 to the substrate 51, whereby a state of the substrate 51 can be favorably maintained.

Note that the lenses 71 and the structure body 72 of the present embodiment are covered with a film on the substrate 51, specifically, covered with the antireflection film 73 on the substrate 51. However, the lenses 71 and the structure body 72 may be formed by a film on the substrate 51. This film may be the antireflection film 73 or a film different from the antireflection film 73. Details of such a film will be described later.

### Second to Fourth Embodiments

### (1) Second Embodiment

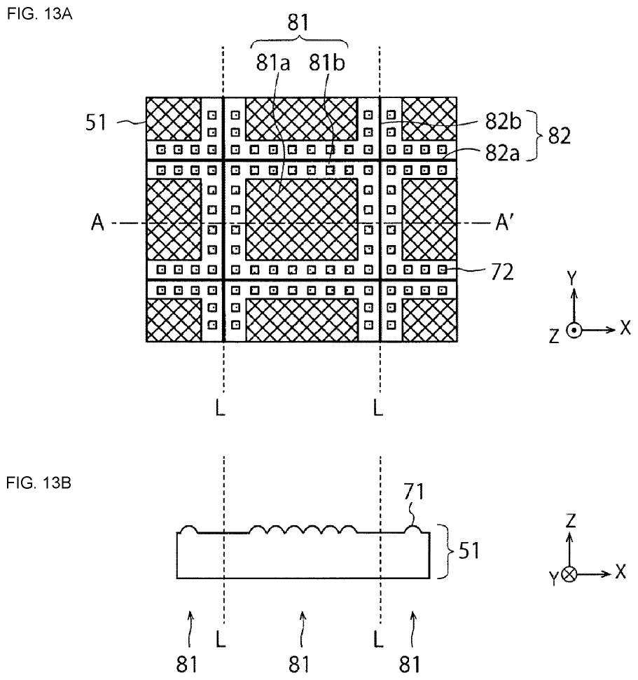

FIG. 13 is a plan view and a cross-sectional view illustrating a structure of a substrate 51 of a light emitting device 1 of a second embodiment. A relationship between A and B in FIG. 13 is similar to a relationship between A and B in FIG. 7.

As illustrated in A of FIG. 13, the substrate 51 of the present embodiment includes multiple lenses 71 and multiple structure bodies 72 in each chip region 81. In each chip region 81, these lenses 71 are disposed in a lens region 81a, and these structure bodies 72 are disposed in the peripheral region 81b. Moreover, these structure bodies 72 are annularly arranged to annularly surround these lenses 71. Therefore, these structure bodies 72 have a shape similar to the structure body 72 in each chip region 81 illustrated in A of FIG. 7. As a result, progress of peeling of a dicing tape 83 can be stopped by using the structure body 72 so as not to spread to the lens 71. The structure body 72 illustrated in A of FIG. 7 forms a continuous ring, whereas the multiple structure bodies 72 illustrated in A of FIG. 13 form a discontinuous ring. When the substrate 51 of the present embodiment is diced, each chip region 81 has these structure bodies 72 near corners and edges of a back surface S2 of the substrate 51. A distance between a side surface S3 of the substrate 51 and the structure body 72 of the present embodiment is also desirably set to, for example, 10 to 100 μm.

### (2) Third Embodiment

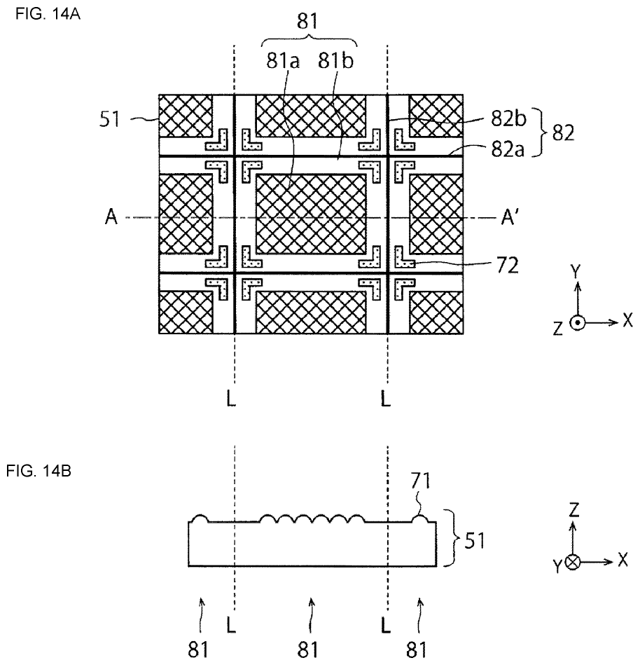

FIG. 14 is a plan view and a cross-sectional view illustrating a structure of a substrate 51 of a light emitting device 1 of a third embodiment. A relationship between A and B in FIG. 14 is similar to the relationship between A and B in FIG. 7.

As illustrated in A of FIG. 14, the substrate 51 of the present embodiment includes multiple lenses 71 and multiple structure bodies 72 in each chip region 81. Each chip region 81 of the present embodiment includes four structure bodies 72 at four corners of a peripheral region 81b, and each structure body 72 has an L-shape in plan view. Peeling of a dicing tape 83 generally tends to progress near these corners of the peripheral region 81b. According to the present embodiment, it is possible to effectively suppress progress of peeling of the dicing tape 83 even when a size of the structure body 72 is small. Note that a shape of each structure body 72 in plan view may be other than the L-shape.

### (3) Fourth Embodiment

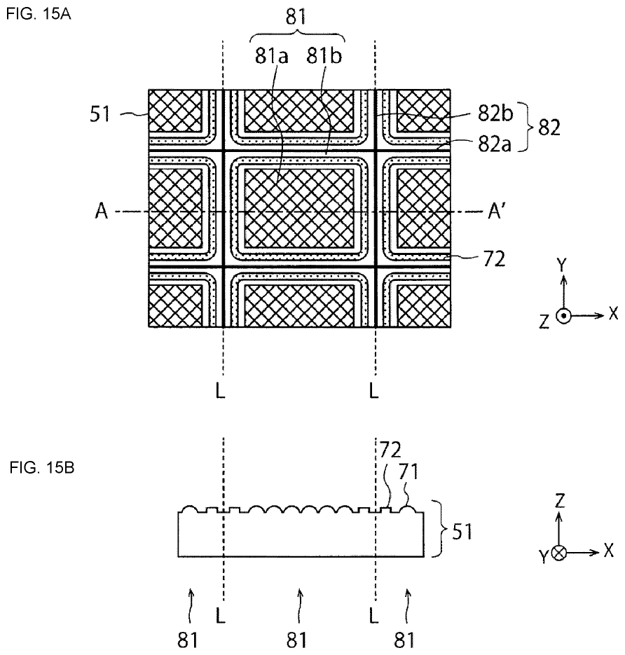

FIG. 15 is a plan view and a cross-sectional view illustrating a structure of a substrate 51 of a light emitting device 1 of a fourth embodiment. A relationship between A and B in FIG. 15 is similar to the relationship between A and B in FIG. 7.

As illustrated in A of FIG. 15, the substrate 51 of the present embodiment includes multiple lenses 71 and one structure body 72 in each chip region 81. Similarly to the structure body 72 illustrated in A of FIG. 7, the structure body 72 of the present embodiment has a shape annularly surrounding these lenses 71. However, the structure body 72 of the present embodiment has a shape (round shape) in which each corner on an inner peripheral side and each corner on an outer peripheral side are rounded. As a result, it is possible to effectively suppress progress of peeling of a dicing tape 83.

Here, advantages of the fourth embodiment will be described with reference to FIG. 10. In FIG. 10, each corner of an adhesive material 83b indicated by reference sign K1 has a round shape. This indicates that peeling of the dicing tape 83 tends to progress so as to generate such a round shape. Therefore, in order to stop progress of the peeling of the dicing tape 83 by using the structure body 72, it is desirable that the structure body 72 also has a round shape. Therefore, the structure body 72 of the present embodiment has a shape (round shape) in which each corner on an inner peripheral side and each corner on an outer peripheral side are rounded.

In these embodiments, similarly to the first embodiment, a height of an uppermost portion of an antireflection film 73 (first portion X1) on each lens 71 is set higher than a height of an uppermost portion of the antireflection film 73 (second portion X2) on the structure body 72. Therefore, according to these embodiments, a light emitting element 53 and the lens 71 can be provided on the substrate 51 in a suitable state.

### Fifth and Sixth Embodiments

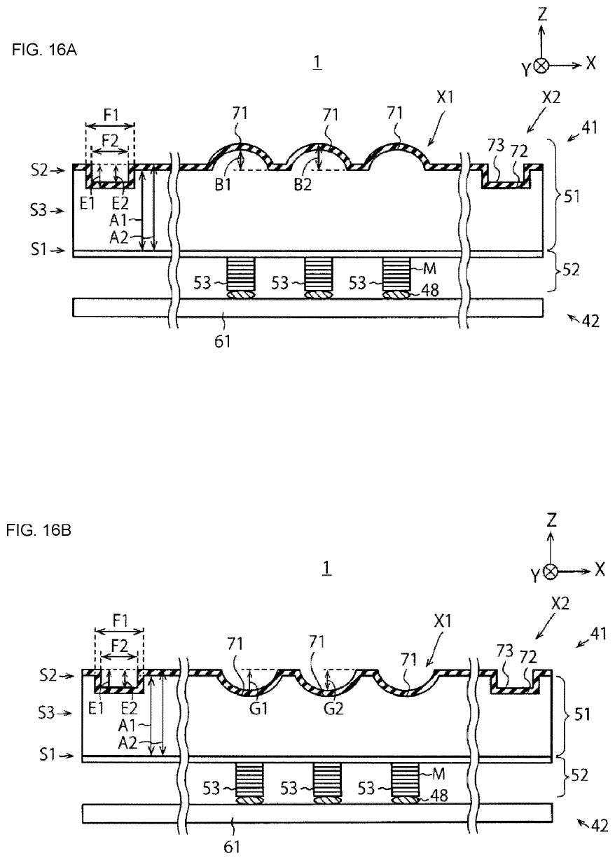

A light emitting device 1 of a fifth embodiment and a light emitting device 1 of a sixth embodiment correspond to light emitting devices 1 of modifications of the first to fourth embodiments. Hereinafter, various examples of the light emitting device 1 of the fifth and sixth embodiments will be described with reference to FIGS. 16 to 21.

### (1) Fifth Embodiment

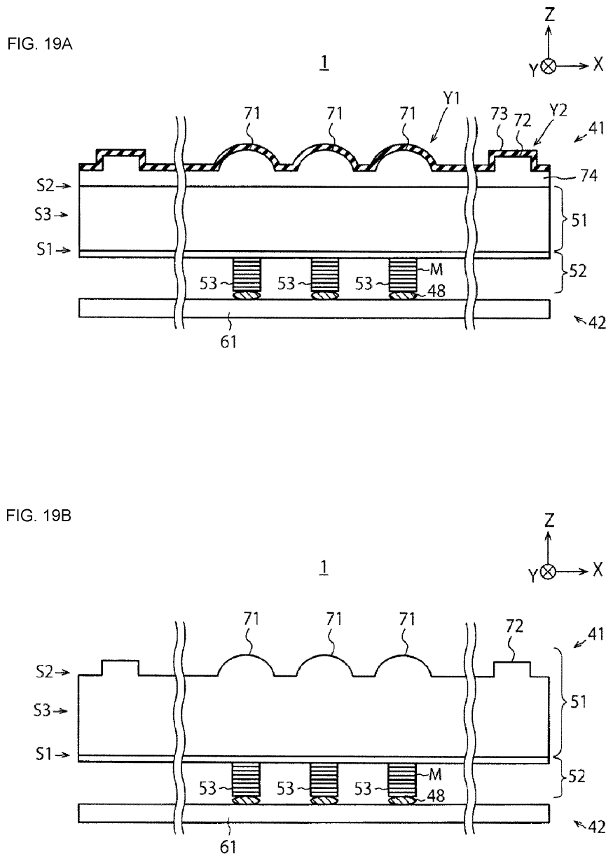

FIGS. 16 to 19 are cross-sectional views illustrating an example of a structure of the light emitting device 1 of the fifth embodiment. Each of A of FIG. 16 to B of FIG. 19 illustrates a cross section of a substrate 51 and the like of the light emitting device 1, similarly to A of FIG. 5.

In the example illustrated in A of FIG. 16, the light emitting device 1 includes multiple lenses 71 that are convex lenses and a structure body 72 having a recessed shape. An antireflection film 73 is provided on a back surface S2 of the substrate 51 so as to cover the lenses 71 and the structure body 72. Therefore, the antireflection film 73 includes a first portion X1 disposed on the lenses 71 and a second portion X2 disposed on the structure body 72. In this example, the first portion X1 also has a convex shape similarly to the lens 71, and the second portion X2 also has a recessed shape similarly to the structure body 72. Shapes of the lens 71 and the structure body 72 in plan view are, for example, the same as shapes of the lens 71 and the structure body 72 illustrated in B of FIG. 5.

A of FIG. 16 illustrates depths E1 and E2 and widths F1 and F2. The depth E1 represents a depth of the structure body 72 in the Z direction, and the width F1 represents a width of the structure body 72 in the X direction in A of FIG. 16. In this example, the thickness A1 of the substrate 51 is, for example, about 100 μm, and the depth E1 of the structure body 72 is, for example, within 20 μm. Moreover, in this example, the width F1 of the structure body 72 is, for example, 10 to 100 μm, and a thickness of the antireflection film 73 is, for example, 0.1 to 1 μm. The depth E2 represents a depth of the second portion X2 in a recessed portion of the structure body 72, and the width F2 represents a width of the second portion X2 in a recessed portion of the structure body 72.

In the first to fourth embodiments, the light emitting device 1 includes the multiple lenses 71 that are convex lenses and the structure body 72 having a protruding shape, and a height of an uppermost portion of the first portion X1 on the lenses 71 is higher than a height of an uppermost portion of the second portion X2 on the structure body 72. The structure body 72 having a recessed shape illustrated in A of FIG. 16 can achieve effects similar to those of the structure body 72 having a protruding shape in the first to fourth embodiments.

For example, according to the example illustrated in A of FIG. 16, by stopping progress of peeling of a dicing tape 83 by using the structure body 72, it is possible to suppress adhesion of an adhesive material 83b of the dicing tape 83 to the lens 71 and the like. This is because the dicing tape 83 is easily caught by a corner (more precisely, a corner of the second portion X2) of the structure body 72 having a recessed shape. Furthermore, according to the example illustrated in A of FIG. 16, since the shape of the structure body 72 is the recessed shape, it is possible to suppress concentration of a load when the dicing tape 83 is bonded to the structure body 72, and it is possible to suppress the adhesive material 83b of the dicing tape 83 from being fixed to the structure body 72.

In this way, according to the example illustrated in A of FIG. 16, the effect obtained by the structure body 72 having a protruding shape in which the height of the first portion X1 is higher than the height of the second portion X2 can be obtained by the structure body 72 having a recessed shape. The values of the depths E1 and E2 in this example may be set to any values, but are desirably set to values with which the substrate 51 is less likely to be broken. Note that, in a case where it is desired to more effectively suppress progress of peeling of the dicing tape 83, it is desirable that the structure body 72 has a protruding shape rather than a recessed shape.

In the example illustrated in B of FIG. 16, the light emitting device 1 includes multiple lenses 71 that are concave lenses and the structure body 72 having a recessed shape. The antireflection film 73 is provided on the back surface S2 of the substrate 51 so as to cover the lenses 71 and the structure body 72. Therefore, the antireflection film 73 includes a first portion X1 disposed on the lenses 71 and a second portion X2 disposed on the structure body 72. In this example, the first portion X1 also has a concave shape similarly to the lens 71, and the second portion X2 also has a recessed shape similarly to the structure body 72. Shapes of the lens 71 and the structure body 72 in plan view are, for example, the same as shapes of the lens 71 and the structure body 72 illustrated in B of FIG. 5.

B of FIG. 16 illustrates depths G1 and G2 in addition to the depths E1 and E2 and the widths F1 and F2 illustrated in A of FIG. 16. The depth G1 represents a depth of the lens 71 in the Z direction, and the depth G2 represents a depth of the first portion X1 in a concave portion of the lens 71. In this example, the thickness A1 of the substrate 51 is, for example, about 100 μm, and the depth G1 of the lens 71 is, for example, within 20 μm. Furthermore, a thickness of the antireflection film 73 is, for example, 0.1 to 1 μm.

The structure body 72 having a recessed shape illustrated in B of FIG. 16 can achieve effects similar to those of the structure body 72 having a protruding shape in the first to fourth embodiments. The reason is similar to the case of the structure body 72 having a recessed shape illustrated in A of FIG. 16. In the example illustrated in B of FIG. 16, the values of the depths E1, E2, G1, and G2 may be set to any values, but are desirably set to values with which the substrate 51 is less likely to be broken. For example, the depth G1 may be deeper or shallower than the depth E1, and the depth G2 may be deeper or shallower than the depth E2.

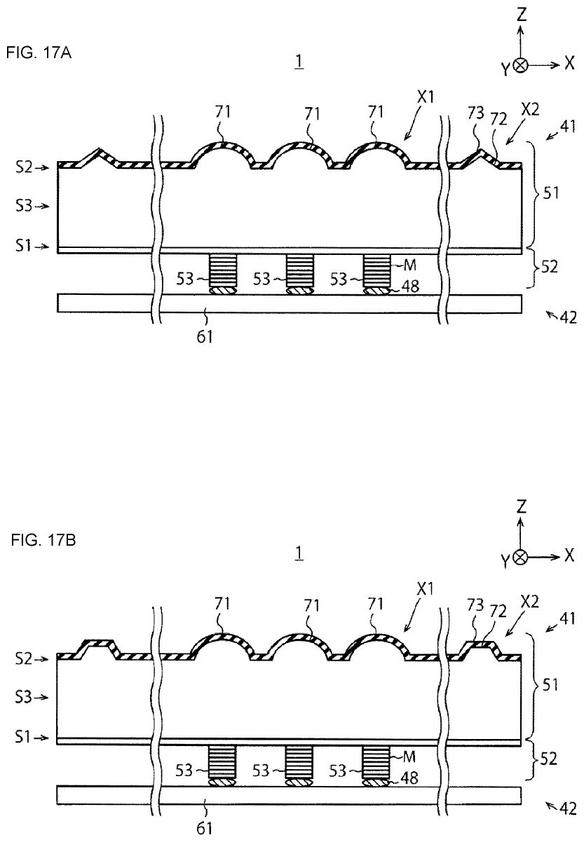

In the example illustrated in A of FIG. 17, the light emitting device 1 includes multiple lenses 71 that are convex lenses, the structure body 72 having a protruding shape, and the antireflection film 73 that covers the lenses 71 and the structure body 72. A shape of a longitudinal cross section of the structure body 72 illustrated in A of FIG. 5 is a quadrangle, whereas a shape of the structure body 72 illustrated in A of FIG. 17 is a triangle. As a result, it is possible to obtain an effect similar to that of the structure body 72 illustrated in A of FIG. 5. In A of FIG. 17, shapes of the lens 71 and the structure body 72 in plan view are, for example, the same as shapes of the lens 71 and the structure body 72 illustrated in B of FIG. 5. Note that such a triangular shape of the longitudinal cross section is also applicable to the structure body 72 having a recessed shape.

In the example illustrated in B of FIG. 17, the light emitting device 1 includes multiple lenses 71 that are convex lenses, the structure body 72 having a protruding shape, and the antireflection film 73 that covers the lenses 71 and the structure body 72. A shape of a longitudinal cross section of the structure body 72 illustrated in A of FIG. 5 is rectangular, whereas a shape of the structure body 72 illustrated in B of FIG. 17 is trapezoidal. As a result, it is possible to obtain an effect similar to that of the structure body 72 illustrated in A of FIG. 5. In B of FIG. 17, shapes of the lens 71 and the structure body 72 in plan view are the same as, for example, shapes of the lens 71 and the structure body 72 illustrated in B of FIG. 5. Note that, such a trapezoidal shape of the longitudinal cross section can also be applied to the structure body 72 having a recessed shape.

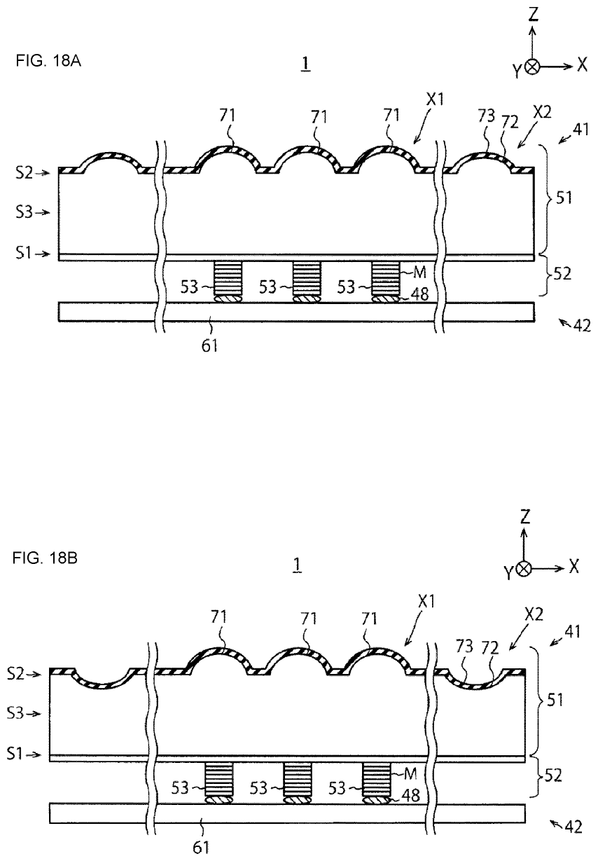

In the example illustrated in A of FIG. 18, the light emitting device 1 includes multiple lenses 71 that are convex lenses, multiple structure bodies 72 having a convex shape, and the antireflection film 73 that covers the lenses 71 and the structure bodies 72. Similarly to the structure body 72 illustrated in A of FIG. 13, these structure bodies 72 are annularly arranged so as to annularly surround these lenses 71. Furthermore, each structure body 72 illustrated in A of FIG. 18 has a convex lens shape similarly to the lens 71, but is not used as the lens 71. According to the example illustrated in A of FIG. 18, it is possible to obtain effects similar to those of the structure bodies 72 of the first to fourth embodiments. Furthermore, according to the example illustrated in A of FIG. 18, the structure body 72 can be formed by a process similar to the process of forming the lens 71.

In the example illustrated in B of FIG. 18, the light emitting device 1 includes multiple lenses 71 that are convex lenses, multiple structure bodies 72 having a concave shape, and the antireflection film 73 that covers the lenses 71 and the structure bodies 72. Similarly to the structure body 72 illustrated in A of FIG. 13, these structure bodies 72 are annularly arranged so as to annularly surround these lenses 71. Furthermore, each structure body 72 illustrated in B of FIG. 18 has a concave lens shape similarly to the lens 71 illustrated in B of FIG. 16, but is not used as the lens 71. According to the example illustrated in B of FIG. 18, it is possible to obtain effects similar to those of the structure bodies 72 of the first to fourth embodiments. Furthermore, according to the example illustrated in B of FIG. 18, the structure body 72 can be formed by a process similar to the process of forming the lens 71 illustrated in B of FIG. 16.

In the example illustrated in A of FIG. 19, the light emitting device 1 includes a semiconductor film 74 in addition to the lens 71, the structure body 72, the antireflection film 73, and the like. In A of FIG. 19, the semiconductor film 74 is formed on the back surface S2 of the substrate 51. Furthermore, the lenses 71 and the structure body 72 are provided as a part of the semiconductor film 74 on an upper surface of the semiconductor film 74. Furthermore, the antireflection film 73 is formed on the upper surface of the semiconductor film 74 so as to cover the lenses 71 and the structure body 72. The antireflection film 73 and the semiconductor film 74 in A of FIG. 19 are examples of a film of the present disclosure. Specifically, the antireflection film 73 is a film disposed on the lens 71 and the structure body 72, and the semiconductor film 74 is a film forming the lens 71 and the structure body 72. The semiconductor film 74 is, for example, a silicon (Si) film.

The antireflection film 73 and the semiconductor film 74 in A of FIG. 19 include a first portion Y1 disposed on the lenses 71 or forming the lenses 71 and a second portion Y2 disposed on the structure body 72 or forming the structure body 72. Then, a height of an uppermost portion of each lens 71 is higher than a height of an uppermost portion of the structure body 72. As a result, a height of an uppermost portion of the first portion Y1 of the antireflection film 73 and the semiconductor film 74 is higher than a height of an uppermost portion of the second portion Y2 of the antireflection film 73 and the semiconductor film 74. As a result, it is possible to stop progress of peeling of the dicing tape 83 by using the structure body 72, and to suppress concentration of a load on the structure body 72 when the dicing tape 83 is bonded.

Note that the antireflection film 73 illustrated in A of FIG. 19 may be understood as a film forming the structure body 72, instead of being understood as a film disposed on the structure body 72. In both cases of the former and the latter, the height of the uppermost portion of the first portion Y1 of the antireflection film 73 and the semiconductor film 74 is set higher than the height of the uppermost portion of the second portion Y2 of the antireflection film 73 and the semiconductor film 74. This similarly applies to the antireflection film 73 of the first to fourth embodiments and the antireflection film 73 of other examples of the fifth embodiment.

In the example illustrated in B of FIG. 19, the light emitting device 1 includes the lenses 71, the structure body 72, and the like similarly to the light emitting device 1 illustrated in A of FIG. 5, but does not include the antireflection film 73. In this way, the light emitting device 1 of the present embodiment may not include the antireflection film 73. In this case, the dicing tape 83 comes into contact with the back surface S2 of the substrate 51 instead of the upper surface of the antireflection film 73.

In B of FIG. 19, a height of an uppermost portion of each lens 71 is higher than a height of an uppermost portion of the structure body 72. As a result, it is possible to stop progress of peeling of the dicing tape 83 by using the structure body 72, and to suppress concentration of a load on the structure body 72 when the dicing tape 83 is bonded.

Note that, in the example illustrated in B of FIG. 19, the light emitting device 1 may include the lenses 71 and the structure body 72 having the shape illustrated in A of FIG. 16, or may include the lenses 71 and the structure body 72 having the shape illustrated in B of FIG. 16. That is, the light emitting device 1 in this example may include the lenses 71 that are concave lenses and the structure body 72 having a recessed shape. Also in this case, it is possible to stop progress of peeling of the dicing tape 83 by using the structure body 72, and to suppress concentration of a load on the structure body 72 when the dicing tape 83 is bonded.

### (2) Sixth Embodiment

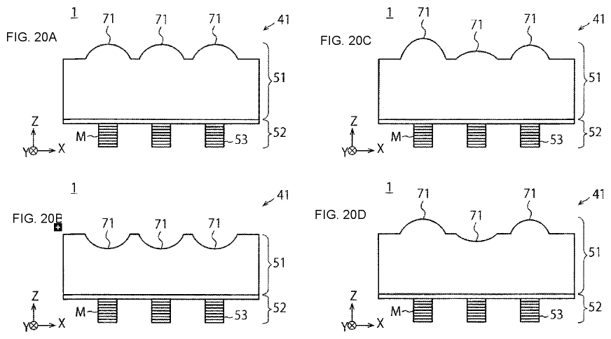

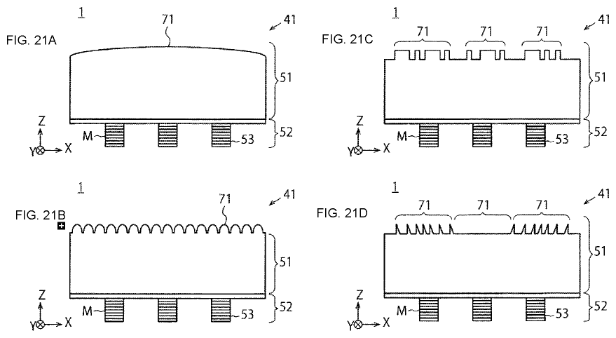

FIGS. 20 and 21 are cross-sectional views illustrating examples of a structure of a substrate 51 of the light emitting device 1 of the sixth embodiment. Each of A of FIG. 20 to D of FIG. 21 illustrates a cross section of the substrate 51 and the like of the light emitting device 1 similarly to A of FIG. 4, but illustration of the structure body 72, the antireflection film 73, and the like is omitted.

Similarly to the substrate 51 in A of FIG. 20, the substrate 51 in A of FIG. 5 includes multiple lenses 71 that is convex lenses corresponding to light emitting elements 53 on a one-to-one basis. Similarly, each substrate 51 of B, C, and D of FIG. 20 includes multiple lenses 71 corresponding to the light emitting elements 53 on a one-to-one basis. However, the substrate 51 in B of FIG. 20 includes concave lenses, the substrate 51 in C of FIG. 20 includes convex lenses having different shapes (curvatures), and the substrate 51 in D of FIG. 20 includes both convex lenses and concave lenses. In this way, each lens 71 of the present embodiment may be a convex lens or a concave lens. Furthermore, as described later, each lens 71 of the present embodiment may be a lens having a convex shape in a form other than the convex lens, or may be a lens having a concave shape in a form other than the concave lens.

In the substrate 51 in A of FIG. 21, the light emitting elements 53 and the lenses 71 correspond to each other at N:1 (N is an integer of 2 or more). Therefore, in A of FIG. 21, light emitted from N light emitting elements 53 is incident on one lens 71. Meanwhile, in the substrate 51 in B of FIG. 21, the light emitting elements 53 and the lenses 71 correspond to each other at 1:N. Therefore, in B of FIG. 21, light emitted from one light emitting element 53 is incident on N lenses 71. In this way, each lens 71 of the present embodiment may not correspond to the light emitting element 53 at 1:1.

In the substrate 51 in C of FIG. 21, the light emitting elements 53 and the lenses 71 correspond to each other at 1:1. However, the substrate 51 in C of FIG. 21 includes a Fresnel lens having a convex shape. Furthermore, in the substrate 51 in D of FIG. 21, the light emitting element 53 and the lens 71 correspond to each other at 1:1. However, the substrate 51 in D of FIG. 21 includes a binary lens having a convex shape and a flat lens. In this way, each lens 71 of the present embodiment may be a lens other than a convex lens or a concave lens.

### Seventh and Eighth Embodiments

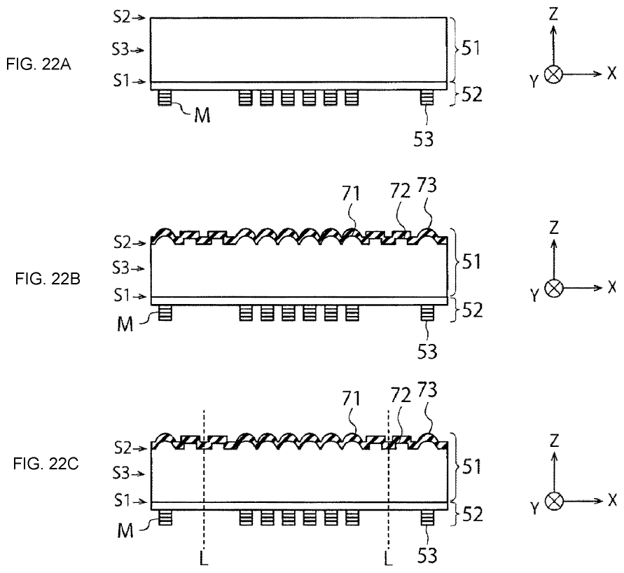

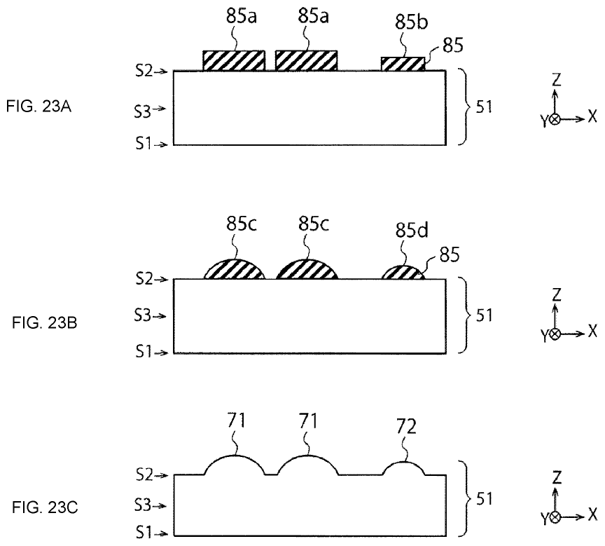

The light emitting device 1 of the first to sixth embodiments can be manufactured by, for example, a method of a seventh embodiment or a method of an eighth embodiment. Hereinafter, with reference to FIGS. 22 and 23, a manufacturing method for a light emitting device 1 of the seventh and eighth embodiments will be described.

### (1) Seventh Embodiment

FIG. 22 is a cross-sectional view illustrating a manufacturing method for the light emitting device 1 of the seventh embodiment.

First, the laminated film 52 is formed on the front surface S1 of the substrate 51, and the mesa portions M including the light emitting elements 53 are formed on the laminated film 52 (A of FIG. 22). Specifically, the laminated film 52 and the mesa portion M are formed on the front surface S1 of the substrate 51 in a state where the front surface S1 of the substrate 51 faces upward, and then the front surface S1 of the substrate 51 is directed downward. In the process illustrated in A of FIG. 22, the anode electrode 54 and the cathode electrode 55, which are not illustrated, are further formed on the front surface S1 of the substrate 51.

Next, the lens 71 and the structure body 72 are formed on the back surface S2 of the substrate 51 by photolithography and dry etching (B of FIG. 22). The lens 71 and the structure body 72 of the present embodiment are formed as a part of the substrate 51 on the back surface S2 of the substrate 51. Note that the lenses 71 and the structure body 72 are simultaneously formed by the same etching in the present embodiment, but may be formed in order by different etching. Next, the antireflection film 73 is formed on the back surface S2 of the substrate 51 so as to cover the lenses 71 and the structure body 72 (B of FIG. 22). The antireflection film 73 is formed by sputtering, for example.

As described above, the lens 71 and the structure body 72 of the present embodiment are formed such that a height of an uppermost portion of each lens 71 is higher than a height of an uppermost portion of the structure body 72 (see A of FIG. 5). As a result, as described above, the antireflection film 73 of the present embodiment is formed such that a height of an uppermost portion of the first portion X1 on each lens 71 is higher than a height of an uppermost portion of the second portion X2 on the structure body 72 (see A of FIG. 5).

Next, the substrate 51 is diced as indicated by reference sign L (C of FIG. 22). The dicing of the substrate 51 is performed by, for example, the method illustrated in A to C of FIG. 9. As a result, the substrate 51 is cut in the above-described scribe region 82 and divided into the above-described multiple chip regions 81. In this way, the light emitting device 1 of the present embodiment is manufactured.

### (2) Eighth Embodiment

FIG. 23 is a cross-sectional view illustrating a manufacturing method for the light emitting device 1 of the eighth embodiment. The method illustrated in FIG. 23 corresponds to an example of the process illustrated in B of FIG. 22. However, in FIG. 23, illustration of the laminated film 52, the light emitting element 53, and the like is omitted.

First, a resist film 85 is formed on the back surface S2 of the substrate 51, and the resist film 85 is patterned by photolithography and dry etching (A of FIG. 23). As a result, the resist film 85 is processed into multiple protrusions 85a for forming the multiple lenses 71 and multiple protrusions 85b for forming the multiple structure bodies 72. FIG. 23A illustrates two of the multiple protrusions 85a and one of the multiple protrusions 85b.

Next, the resist film 85 is heated (B of FIG. 23). As a result, the multiple protrusions 85a described above are changed to multiple protrusions 85c having a longitudinal cross-sectional shape like a convex lens, and the multiple protrusions 85b are also changed to multiple protrusions 85d having a longitudinal cross-sectional shape like a convex lens. In the process illustrated in B of FIG. 23, the resist film 85 is heated to, for example, about 150° C.

Next, a pattern of the resist film 85 is transferred to the back surface S2 of the substrate 51 by dry etching using the resist film 85 as a mask (C of FIG. 23). As a result, the multiple lenses 71 and the multiple structure bodies 72 are formed on the back surface S2 of the substrate 51. According to the process illustrated in C of FIG. 23, the lens 71 and the structure body 72 illustrated in A of FIG. 18 are formed. Therefore, each lens 71 of the present embodiment is a convex lens, and each structure body 72 of the present embodiment is a protruding portion having a convex lens shape.

Thereafter, the antireflection film 73 is formed on the back surface S2 of the substrate 51 so as to cover the lenses 71 and the structure body 72. In this way, the structure illustrated in B of FIG. 22 is realized. However, each structure body 72 of the present embodiment is a protruding portion having a convex lens shape. Since the structure body 72 of the present embodiment has a shape similar to that of the lens 71, the structure body 72 can be easily and inexpensively formed simultaneously with the lens 71.

Note that the manufacturing method for the light emitting device 1 of the present embodiment can also be applied to manufacturing a light emitting device 1 other than the light emitting device 1 illustrated in A of FIG. 18.

### Ninth and Tenth Embodiments

### (1) Ninth Embodiment

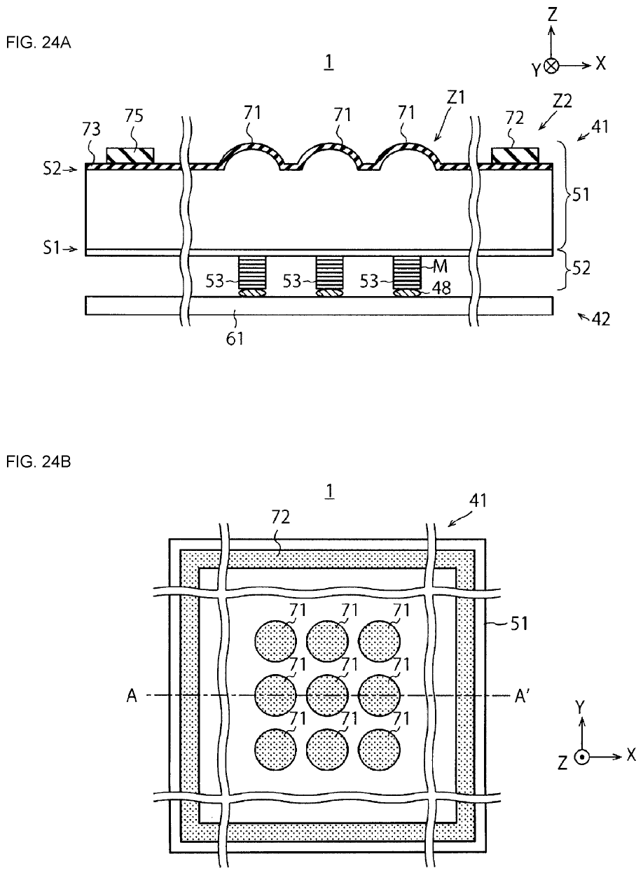

FIG. 24 is a cross-sectional view and a plan view illustrating a structure of a light emitting device 1 of a ninth embodiment.

A of FIG. 24 illustrates cross sections of an LD chip 41 and an LDD substrate 42 in the light emitting device 1, similarly to A of FIG. 5. The LD chip 41 of the present embodiment includes a structure-body forming film 75 in addition to the components illustrated in A of FIG. 5. An antireflection film 73 and the structure-body forming film 75 in A of FIG. 24 are examples of a film of the present disclosure. Note that, in A of FIG. 24, similarly to A of FIG. 5, illustration of anode electrodes 54, cathode electrodes 55, and connection pads 62 is omitted.

The structure body 72 illustrated in A of FIG. 5 is formed by a part of the substrate 51, whereas a structure body 72 of the present embodiment is formed by the structure-body forming film 75. The structure-body forming film 75 is formed on a back surface S2 of a substrate 51 via the antireflection film 73. The structure-body forming film 75 is, for example, a light absorbing film, an inorganic film, or an organic film. The structure body 72 of the present embodiment has a shape annularly surrounding all lenses 71 on the substrate 51, similarly to the structure body 72 illustrated in B of FIG. 5.

As described above, the LD chip 41 of the present embodiment includes the antireflection film 73 and the structure-body forming film 75 on the back surface S2 of the substrate 51. The antireflection film 73 and the structure-body forming film 75 of the present embodiment include a first portion Z1 disposed on the lens 71 and a second portion Z2 forming the structure body 72. The first portion 21 includes only the antireflection film 73 among the antireflection film 73 and the structure-body forming film 75. The second portion Z2 includes only the structure-body forming film 75 among the antireflection film 73 and the structure-body forming film 75.

In the present embodiment, similarly to the first embodiment (A of FIG. 5), a height of an uppermost portion of each lens 71 is higher than a height of an uppermost portion of the structure body 72. In other words, the Z coordinate of the uppermost portion of each lens 71 is larger than the Z coordinate of the uppermost portion of the structure body 72. Since each lens 71 of the present embodiment is a convex lens, the uppermost portion of each lens 71 is a top portion of each lens 71. Whereas, since the structure body 72 of the present embodiment has a protruding shape and has a flat upper surface, the uppermost portion of the structure body 72 is an upper surface of the structure body 72. Therefore, in the present embodiment, a height of the top portion of each lens 71 is higher than a height of the upper surface of the structure body 72. Furthermore, in the present embodiment, a height of an uppermost portion of the first portion 21 on each lens 71 is higher than a height of an uppermost portion of the second portion 22 in the structure body 72. Therefore, according to the present embodiment, it is possible to stop progress of peeling of a dicing tape 83 by using the structure body 72, and to suppress concentration of a load on the structure body 72 when the dicing tape 83 is bonded.

B of FIG. 24 illustrates a layout of the lenses 71 and the structure body 72 provided on the back surface S2 of the substrate 51. The layout of the lenses 71 and the structure body 72 of the present embodiment is similar to the layout of the lenses 71 and the structure body 72 of the first embodiment (B of FIG. 5). A of FIG. 24 illustrates a cross section taken along line A-A′ illustrated in B of FIG. 24.

The structure-body forming film 75 is, for example, a light absorbing film having a function of absorbing light. As a result, it is possible to suppress stray light in the substrate 51 from being reflected by the structure-body forming film 75, and it is possible to suppress occurrence of color mixing.

The structure-body forming film 75 may be, for example, an inorganic film formed by an inorganic material. Generally, since the inorganic film is a film having rigidity, rigidity can be imparted to the structure-body forming film 75 by forming the structure-body forming film 75 with an inorganic material. As a result, when the dicing tape 83 is bonded to the substrate 51, it is possible to suppress the substrate 51 from being warped by pressure from the dicing tape 83.

The structure-body forming film 75 may be, for example, an organic film formed by an organic material. Generally, since the organic film is a film having elasticity, elasticity can be imparted to the structure-body forming film 75 by forming the structure-body forming film 75 with an organic material. As a result, when the dicing tape 83 is bonded to the substrate 51, pressure from the dicing tape 83 to the substrate 51 can be dispersed.

### (2) Tenth Embodiment

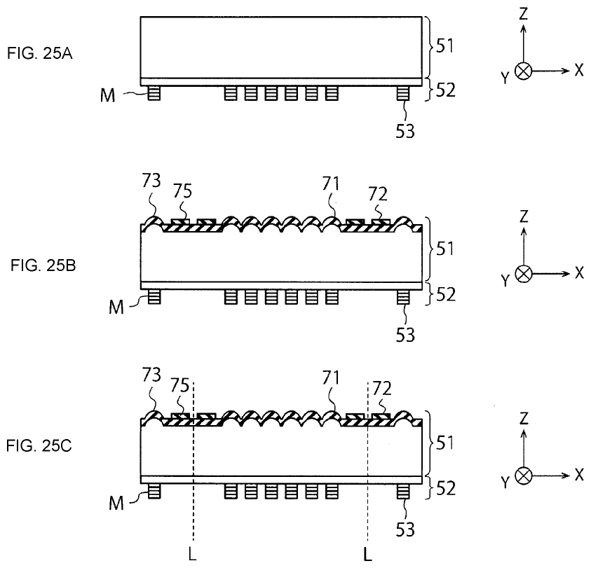

FIG. 25 is a cross-sectional view illustrating a manufacturing method for a light emitting device 1 of a tenth embodiment. The light emitting device 1 of the ninth embodiment can be manufactured by, for example, the method of the present embodiment.

First, the laminated film 52 is formed on the front surface S1 of the substrate 51, and the mesa portions M including light emitting elements 53 are formed on the laminated film 52 (A of FIG. 25). Specifically, the laminated film 52 and the mesa portion M are formed on the front surface S1 of the substrate 51 in a state where the front surface S1 of the substrate 51 faces upward, and then the front surface S1 of the substrate 51 is directed downward. In the process illustrated in A of FIG. 25, the anode electrode 54 and the cathode electrode 55, which are not illustrated, are further formed on the front surface S1 of the substrate 51.

Next, the lenses 71 are formed on the back surface S2 of the substrate 51 by photolithography and dry etching (B of FIG. 25). The lenses 71 of the present embodiment are formed as part of the substrate 51 on the back surface S2 of the substrate 51. Next, the antireflection film 73 is formed on the back surface S2 of the substrate 51 so as to cover the lenses 71 (B of FIG. 25). The antireflection film 73 is formed by sputtering, for example. Next, the structure-body forming film 75 is formed on the antireflection film 73, and the structure-body forming film 75 is processed into the structure body 72 by photolithography and dry etching (B of FIG. 25).

As described above, the lens 71 and the structure body 72 of the present embodiment are formed such that a height of an uppermost portion of each lens 71 is higher than a height of an uppermost portion of the structure body 72. As a result, a height of an uppermost portion of the first portion Z1 disposed on each lens 71 is made higher than a height of an uppermost portion of the second portion 22 forming the structure body 72 (see A of FIG. 24).

Next, the substrate 51 is diced as indicated by reference sign L (C of FIG. 25). The dicing of the substrate 51 is performed by, for example, the method illustrated in A to C of FIG. 9. As a result, the substrate 51 is cut in the above-described scribe region 82 and divided into the above-described multiple chip regions 81. In this way, the light emitting device 1 of the present embodiment is manufactured.

Note that the light emitting device 1 of the first to tenth embodiments is used as a light source of the distance measuring device 101, but may be used in other modes. For example, the light emitting devices 1 of these embodiments may be used as a light source of an optical apparatus such as a printer, or may be used as a lighting device.

Although the embodiments of the present disclosure have been described above, these embodiments may be implemented with various modifications within a scope not departing from the gist of the present disclosure. For example, two or more embodiments may be implemented in combination.

Note that the present disclosure can also have the following configurations.
(1)

A light emitting device including:
a first substrate;
a light emitting element provided on a lower surface of the first substrate;
a lens provided on an upper surface of the first substrate and having a convex shape or a concave shape;
a structure body that is provided on the upper surface of the first substrate, has a protruding shape or a recessed shape, and is different from the lens; and
a film provided on the upper surface of the first substrate, the film including a first portion disposed on the lens or forming the lens, and a second portion disposed on the structure body or forming the structure body, in which
in a case where the lens has a convex shape, the structure body has a protruding shape, and a height of an uppermost portion of the first portion is higher than a height of an uppermost portion of the second portion, or the structure body has a recessed shape, and
in a case where the lens has a concave shape, the structure body has a recessed shape.
(2)

The light emitting device according to (1), in which the lens is a convex lens, a concave lens, a Fresnel lens, or a binary lens.
(3)

The light emitting device according to (1), in which
one or more of the light emitting element are provided on the lower surface of the first substrate,
one or more of the lens are provided on the upper surface of the first substrate, and
the light emitting element and the lens correspond to each other at 1:1, N:1, or 1:N (N is an integer of 2 or more).
(4)

The light emitting device according to (1), in which the structure body has a shape annularly surrounding the lens.
(5)

The light emitting device according to (4), in which the structure body has a shape in which a corner on an inner peripheral side or an outer peripheral side is rounded.
(6)

The light emitting device according to (1), further including, as the structure body, multiple structure bodies provided at multiple corners or edges of the upper surface of the first substrate.
(7)

The light emitting device according to (6), in which the multiple structure bodies are annularly arranged so as to annularly surround the lens.
(8)

The light emitting device according to (1), in which a shape of a longitudinal cross section of the structure body is a quadrangular shape, a triangular shape, a convex lens shape, or a concave lens shape.
(9)

The light emitting device according to (1), in which a distance between a side surface of the first substrate and the structure body is 10 to 100 μm.
(10)

The light emitting device according to (1), further including a modified layer provided on a side surface of the first substrate.
(11)

The light emitting device according to (1), in which the film includes an antireflection film provided on the lens.
(12)

The light emitting device according to (1), in which the film includes an antireflection film provided on the lens, and includes a light absorbing film, an inorganic film, or an organic film different from the antireflection film.
(13)

The light emitting device according to (13), in which the light absorbing film, the inorganic film, or the organic film is provided on the antireflection film.
(14)

The light emitting device according to (1), in which the first substrate is a semiconductor substrate containing gallium (Ga) and arsenic (As).
(15)

The light emitting device according to (1), in which light emitted from the light emitting element passes through the first substrate from the lower surface to the upper surface of the first substrate, and enters the lens.
(16)

The light emitting device according to (1), further including a second substrate on which the first substrate is mounted with the light emitting element interposed therebetween.
(17)

The light emitting device according to (16), in which the second substrate is a semiconductor substrate containing silicon (Si).
(18)

A light emitting device including:
a first substrate;
a light emitting element provided on a lower surface of the first substrate;
a lens provided on an upper surface of the first substrate and having a convex shape or a concave shape; and
a structure body that is provided on the upper surface of the first substrate, has a protruding shape or a recessed shape, and is different from the lens, in which
in a case where the lens has a convex shape, the structure body has a protruding shape, and a height of an uppermost portion of the lens is higher than a height of an uppermost portion of the structure body, or the structure body has a recessed shape, and
in a case where the lens has a concave shape, the structure body has a recessed shape.
(19)

A distance measuring device including:
a light emitting unit including a light emitting element that generates light, and configured to irradiate a subject with light from the light emitting element;
a light receiving unit configured to receive light reflected from the subject; and
a distance measuring unit configured to measure a distance to the subject on the basis of light received by the light receiving unit, in which
the light emitting unit includes:
a first substrate;
the light emitting element provided on a lower surface of the first substrate;
a lens provided on an upper surface of the first substrate and having a convex shape or a concave shape;
a structure body that is provided on the upper surface of the first substrate, has a protruding shape or a recessed shape, and is different from the lens; and
a film provided on the upper surface of the first substrate, the film including a first portion disposed on the lens or forming the lens, and a second portion disposed on the structure body or forming the structure body,
in a case where the lens has a convex shape, the structure body has a protruding shape, and a height of an uppermost portion of the first portion is higher than a height of an uppermost portion of the second portion, or the structure body has a recessed shape, and
in a case where the lens has a concave shape, the structure body has a recessed shape.
(20)

A distance measuring device including:
a light emitting unit including a light emitting element that generates light, and configured to irradiate a subject with light from the light emitting element;
a light receiving unit configured to receive light reflected from the subject; and
a distance measuring unit configured to measure a distance to the subject on the basis of light received by the light receiving unit, in which
the light emitting unit includes:
a first substrate;
the light emitting element provided on a lower surface of the first substrate;
a lens provided on an upper surface of the first substrate and having a convex shape or a concave shape; and
a structure body that is provided on the upper surface of the first substrate, has a protruding shape or a recessed shape, and is different from the lens,
in a case where the lens has a convex shape, the structure body has a protruding shape, and a height of an uppermost portion of the lens is higher than a height of an uppermost portion of the structure body, or the structure body has a recessed shape, and
in a case where the lens has a concave shape, the structure body has a recessed shape.

### REFERENCE SIGNS LIST

1 Light emitting device
41 LD chip
42 LDD substrate
43 Mounting substrate
44 Heat dissipation substrate
45 Correction lens holding unit
46 Correction lens
47 Wiring
48 Bump
51 Substrate
52 Laminated film
53 Light emitting element
54 Anode electrode
55 Cathode electrode
61 Substrate
62 Connection pad
71 Lens
72 Structure body
73 Antireflection film
74 Semiconductor film
75 Structure-body forming film
81 Chip region
81a Lens region
81b Peripheral region
82 Scribe region
82a Scribe line
82b Scribe line
83 Dicing tape
83a Base material
83b Adhesive material
84 Modified layer
85 Resist film
85a Protrusion
85b Protrusion
85c Protrusion
85d Protrusion
101 Distance measuring device
102 Light emitting unit
102a Light emitting element
103 Drive unit
104 Power supply circuit
105 Light-emitting side optical system
106 Light-receiving side optical system
107 Light receiving unit
108 Signal processing unit
109 Control unit
109a Distance measuring unit
110 Temperature detection unit

1. A light emitting device comprising:
a first substrate;
a light emitting element provided on a lower surface of the first substrate;
a lens provided on an upper surface of the first substrate and having a convex shape or a concave shape;
a structure body that is provided on the upper surface of the first substrate, has a protruding shape or a recessed shape, and is different from the lens; and
a film provided on the upper surface of the first substrate, the film including a first portion disposed on the lens or forming the lens, and a second portion disposed on the structure body or forming the structure body, wherein
in a case where the lens has a convex shape, the structure body has a protruding shape, and a height of an uppermost portion of the first portion is higher than a height of an uppermost portion of the second portion, or the structure body has a recessed shape, and
in a case where the lens has a concave shape, the structure body has a recessed shape.

2. The light emitting device according to claim 1, wherein the lens includes a convex lens, a concave lens, a Fresnel lens, or a binary lens.

3. The light emitting device according to claim 1, wherein
one or more of the light emitting element are provided on a lower surface of the first substrate,
one or more of the lens are provided on the upper surface of the first substrate, and
the light emitting element and the lens correspond to each other at 1:1, N:1, or 1:N (N is an integer of 2 or more).

4. The light emitting device according to claim 1, wherein the structure body has a shape annularly surrounding the lens.

5. The light emitting device according to claim 4, wherein the structure body has a shape in which a corner on an inner peripheral side or an outer peripheral side is rounded.

6. The light emitting device according to claim 1, further comprising, as the structure body, multiple structure bodies provided at multiple corners or edges of the upper surface of the first substrate.

7. The light emitting device according to claim 6, wherein the multiple structure bodies are annularly arranged so as to annularly surround the lens.

8. The light emitting device according to claim 1, wherein a shape of a longitudinal cross section of the structure body is a quadrangular shape, a triangular shape, a convex lens shape, or a concave lens shape.

9. The light emitting device according to claim 1, wherein a distance between a side surface of the first substrate and the structure body is 10 to 100 μm.

10. The light emitting device according to claim 1, further comprising a modified layer provided on a side surface of the first substrate.

11. The light emitting device according to claim 1, wherein the film includes an antireflection film provided on the lens.

12. The light emitting device according to claim 1, wherein the film includes an antireflection film provided on the lens, and includes a light absorbing film, an inorganic film, or an organic film different from the antireflection film.

13. The light emitting device according to claim 12, wherein the light absorbing film, the inorganic film, or the organic film is provided on the antireflection film.

14. The light emitting device according to claim 1, wherein the first substrate includes a semiconductor substrate containing gallium (Ga) and arsenic (As).

15. The light emitting device according to claim 1, wherein light emitted from the light emitting element passes through the first substrate from the lower surface to the upper surface of the first substrate, and enters the lens.

16. The light emitting device according to claim 1, further comprising a second substrate on which the first substrate is mounted with the light emitting element interposed therebetween.

17. The light emitting device according to claim 16, wherein the second substrate includes a semiconductor substrate containing silicon (Si).

18. A light emitting device comprising:
a first substrate;
a light emitting element provided on a lower surface of the first substrate;
a lens provided on an upper surface of the first substrate and having a convex shape or a concave shape; and
a structure body that is provided on the upper surface of the first substrate, has a protruding shape or a recessed shape, and is different from the lens, wherein
in a case where the lens has a convex shape, the structure body has a protruding shape, and a height of an uppermost portion of the lens is higher than a height of an uppermost portion of the structure body, or the structure body has a recessed shape, and
in a case where the lens has a concave shape, the structure body has a recessed shape.

19. A distance measuring device comprising:
a light emitting unit including a light emitting element that generates light, and configured to irradiate a subject with light from the light emitting element;
a light receiving unit configured to receive light reflected from the subject; and
a distance measuring unit configured to measure a distance to the subject on a basis of light received by the light receiving unit, wherein
the light emitting unit includes:
a first substrate;
the light emitting element provided on a lower surface of the first substrate;
a lens provided on an upper surface of the first substrate and having a convex shape or a concave shape;
a structure body that is provided on the upper surface of the first substrate, has a protruding shape or a recessed shape, and is different from the lens; and
a film provided on the upper surface of the first substrate, the film including a first portion disposed on the lens or forming the lens, and a second portion disposed on the structure body or forming the structure body,
in a case where the lens has a convex shape, the structure body has a protruding shape, and a height of an uppermost portion of the first portion is higher than a height of an uppermost portion of the second portion, or the structure body has a recessed shape, and
in a case where the lens has a concave shape, the structure body has a recessed shape.

20. A distance measuring device comprising:
a light emitting unit including a light emitting element that generates light, and configured to irradiate a subject with light from the light emitting element;
a light receiving unit configured to receive light reflected from the subject; and
a distance measuring unit configured to measure a distance to the subject on a basis of light received by the light receiving unit, wherein
the light emitting unit includes:
a first substrate;
the light emitting element provided on a lower surface of the first substrate;
a lens provided on an upper surface of the first substrate and having a convex shape or a concave shape; and
a structure body that is provided on the upper surface of the first substrate, has a protruding shape or a recessed shape, and is different from the lens,
in a case where the lens has a convex shape, the structure body has a protruding shape, and a height of an uppermost portion of the lens is higher than a height of an uppermost portion of the structure body, or the structure body has a recessed shape, and
in a case where the lens has a concave shape, the structure body has a recessed shape.
